(19) United States
(12) Patent Application Publication
(10) Pub. No.: US 2024/0063232 A1
(43) Pub. Date: Feb. 22, 2024

(54) DISPLAY PANEL AND DISPLAY APPARATUS

(71) Applicant: Tianma Advanced Display Technology Institute (Xiamen) Co., Ltd., Xiamen (CN)

(72) Inventors: Zhenyu JIA, Xiamen (CN); Yingteng ZHAI, Xiamen (CN); Kerui XI, Xiamen (CN); Tianyi WU, Xiamen (CN); Xiaoxiang HE, Xiamen (CN); Liwei ZHANG, Xiamen (CN); Yingying WU, Xiamen (CN); Yukun HUANG, Xiamen (CN); Aowen LI, Xiamen (CN); Ping AN, Xiamen (CN); Feng QIN, Xiamen (CN)

(73) Assignee: Tianma Advanced Display Technology Institute (Xiamen) Co., Ltd., Xiamen (CN)

(21) Appl. No.: 18/499,769

(22) Filed: Nov. 1, 2023

(30) Foreign Application Priority Data
Jun. 30, 2023 (CN) 202310794238.5

(51) Int. Cl. H01L 27/12; H01L 25/16

(52) U.S. Cl. CPC H01L 27/124; H01L 25/167

(57) ABSTRACT

A display panel and a display apparatus are provided. The display panel has a first display region and a binding region at least partially surrounding the first display region and includes pixel units arranged in the first display region and pads including first and second pads. The pixel units each include a sub-pixel. The binding region includes first and second binding regions. The first pad and the second pad are provided in the first binding region and the second binding region, respectively. A signal transmitted by the first pad is different from a signal transmitted by the second pad.

### CROSS-REFERENCE TO RELATED APPLICATIONS

The present application claims priority to Chinese Patent Application No. 202310794238.5, filed on Jun. 30, 2023, the content of which is incorporated herein by reference in its entirety.

### TECHNICAL FIELD

The present disclosure relates to the technical field of displays, and in particular to a display panel and a display apparatus.

### BACKGROUND

In the display apparatuses in the related art, there are two types of display panels, namely a liquid crystal display (LCD) panel and an organic light-emitting diode (OLED) display panel. The OLED display panel is made of an organic electroluminescent material. The organic electroluminescent material emits light when a current flows through the organic electroluminescent material, thus realizing a display function of the display panel.

According to the display technologies in the related art, the display panel is always provided with a binding region. Pads are provided in the binding region. Through the pads, signals are supplied to the display panel. To ensure normal display and uniform display of the display panel, multiple different signals are supplied to the display panel, and multiple pads are provided in the binding region. Consequently, the space for each pad is small and the display panel is more difficult to manufacture. This is a technical problem to be solved in the art.

### SUMMARY

In view of the above, the present disclosure provides a display panel and a display apparatus, to lower a manufacturing difficulty of the display panel.

According to a first aspect, the present disclosure provides a display panel. The display panel has a first display region and a binding region at least partially surrounding the first display region. The display panel includes pixel units arranged in the first display region, and also includes pads including at least one first pad and at least one second pad. At least one pixel unit includes at least one sub-pixel. The binding region includes a first binding region and a second binding region. The at least one first pad is provided in the first binding region. The at least one second pad is provided in the second binding region. A signal transmitted by each of the at least one first pad is different from a signal transmitted by each of the at least one second pad.

According to a second aspect, the present disclosure further provides a display apparatus including a display panel. The display panel has a first display region and a binding region at least partially surrounding the first display region. The display panel includes pixel units arranged in the first display region, and also includes pads including at least one first pad and at least one second pad. At least one pixel unit includes at least one sub-pixel. The binding region includes a first binding region and a second binding region. The at least one first pad is provided in the first binding region. The at least one second pad is provided in the second binding region. A signal transmitted by each of the at least one first pad is different from a signal transmitted by each of the at least one second pad.

### BRIEF DESCRIPTION OF DRAWINGS

The accompanying drawings, which are incorporated in and constitute a part of the specification, illustrate embodiments of the present disclosure and together with the general description, serve to explain the principles of the present disclosure.

FIG. 1 is a schematic diagram of a display panel in the related art;

FIG. 2 is a schematic diagram of a display panel according to the present disclosure;

FIG. 3 is a schematic diagram of another display panel according to the present disclosure;

FIG. 4 is a schematic view along C-C′ shown in FIG. 3;

FIG. 5 is a schematic diagram of another display panel according to the present disclosure;

FIG. 6 is a schematic diagram of another display panel according to the present disclosure;

FIG. 7 is a schematic diagram of another display panel according to the present disclosure;

FIG. 8 is a schematic diagram of another display panel according to the present disclosure;

FIG. 9 is a schematic diagram of another display panel according to the present disclosure;

FIG. 10 is a schematic diagram of another display panel according to the present disclosure;

FIG. 11 is a schematic diagram of another display panel according to the present disclosure;

FIG. 12 is a schematic diagram of another display panel according to the present disclosure;

FIG. 13 is a schematic diagram of another display panel according to the present disclosure;

FIG. 14 is a schematic view along A-A′ shown in FIG. 2;

FIG. 15 is a schematic diagram of a back surface of a display panel according to the present disclosure;

FIG. 16 is a schematic diagram of a back surface of another display panel according to the present disclosure;

FIG. 17 is a schematic diagram of a back surface of another display panel according to the present disclosure;

FIG. 18 is a schematic view along B-B′ shown in FIG. 2;

FIG. 19 is another schematic view along C-C′ shown in FIG. 3;

FIG. 20 is a schematic view along E-E′ shown in FIG. 2;

FIG. 21 is a schematic view along D-D′ shown in FIG. 3;

FIG. 22 is a schematic diagram of a display apparatus according to the present disclosure;

FIG. 23 is a schematic diagram of another display apparatus according to the present disclosure;

FIG. 24 is a schematic diagram of another display apparatus according to the present disclosure; and

FIG. 25 is a schematic diagram of another display apparatus according to the present disclosure.

### DESCRIPTION OF EMBODIMENTS

The exemplary embodiments of the present disclosure are described below with reference to the drawings. Unless otherwise specified, the relative arrangement, numerical expressions, and numerical values of components and steps described in these embodiments do not limit the scope of the present disclosure.

The following description of at least one exemplary example is merely illustrative, and not intended to limit the present disclosure and application or use thereof in any way.

The technologies, methods, and devices known to those of ordinary skill in the art may not be discussed in detail, but where appropriate, the technologies, methods, and devices should be regarded as part of the specification.

In all examples shown and discussed herein, any specific value should be interpreted as merely exemplary, rather than being presented as a limitation. Therefore, other examples of the exemplary embodiments may have different values.

Similar reference numerals and letters represent similar items in the drawings below. Therefore, once an item is defined in one drawing, it does not need to be further discussed in subsequent drawings.

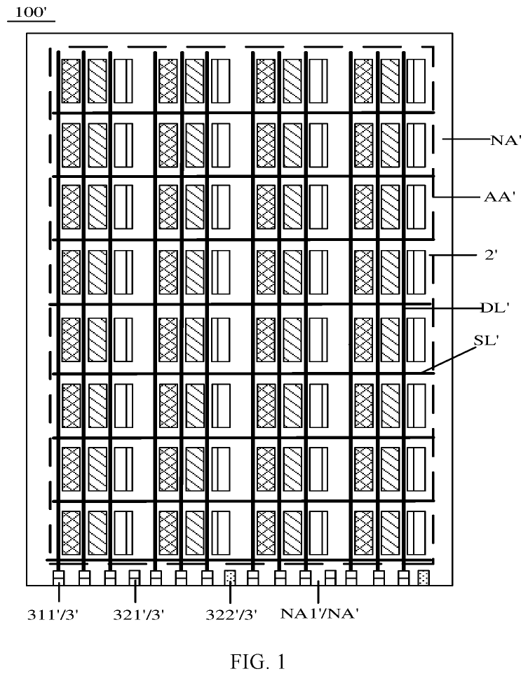

In view of overall hard manufacture of a display panel in the related art, the following research is conducted on the related art. FIG. 1 is a schematic diagram of a display panel in the related art. Referring to FIG. 1, according to a conventional display manufacturing technology, a display panel 100′ includes a display region AA′ and a binding region NA′ surrounding the display region AA′. The display region AA′ includes pixel units 2′. The pixel units 2′ are arranged in an array. The binding region NA′ includes a lower binding region NA1′. When manufacturing traces, each column of the pixel units 2′ includes at least three data lines DL′. Meanwhile, in order to increase signal uniformity of the display panel 100′, a driving voltage line (not shown in the figure) is connected to the pixel unit 2′ (for a PVDD signal and a PVEE signal, the PVDD signal and the PVEE signal each can be a power signal). The driving voltage line is provided in the display panel 100′. The driving voltage line is electrically connected to the pad 3′ located in the binding region NA′. At least two columns of the pixel units 2′ correspond to only one pad 3′. For example, the driving voltage line is provided at least every several columns of the pixel units 2′. As shown in FIG. 1, every two columns of the pixel units 2′ are provided with one PVDD signal and one PVEE signal, or each column of the pixel units 2′ is provided with the PVDD signal and the PVEE signal, or more columns of the pixel units 2′ are provided with one PVDD signal and one PVEE signal. With the above solution, due to a small number of pads 3′ provided in the binding region NA′, the PVDD signal and the PVEE signal in the display panel 100′ are not uniform. Namely, as shown in FIG. 1, a data signal pad 311′, a PVDD signal pad 321′, and a PVEE signal pad 322′ are provided in the lower binding region NA1′ along a row direction. In the high pixels per inch (PPI) display panel, the space for each pad of the trace is small. For example, a spacing between the pads, i.e., a distance from a geometric center of one pad of two adjacent pads to a geometric center of the other pad of the two adjacent pads, is too small, which is out of the manufacturing capacity, and the spacing between the pads is often 90 μm.

In order to reduce a manufacturing difficulty of the display panel, the present disclosure provides a display panel and a display apparatus. Some embodiments of the display panel are described in detail as follows.

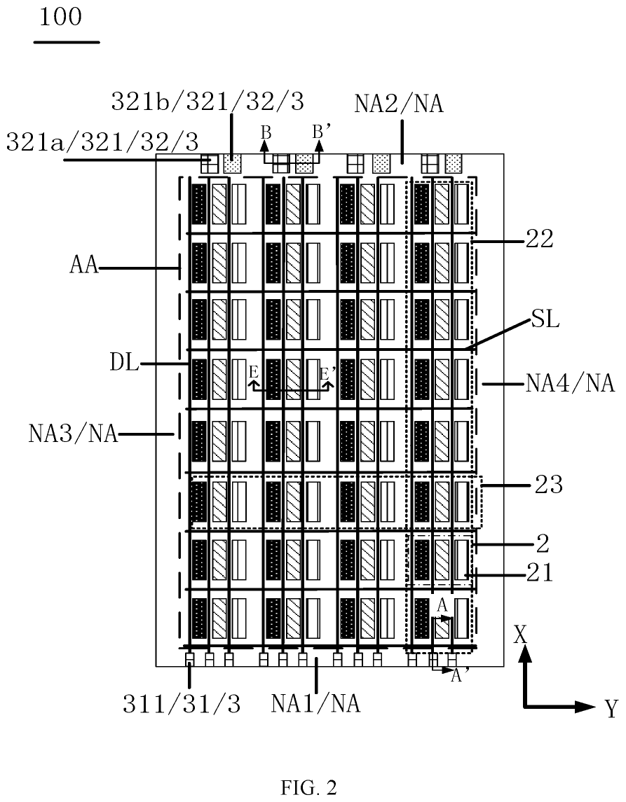

FIG. 2 is a schematic diagram of a display panel according to the present disclosure. Referring to FIG. 2, the display panel 100 provided by the embodiment of the present disclosure has a first display region AA and a binding region NA at least partially surrounding the first display region AA. The display panel 100 includes pixel units 2 arranged in the first display region AA. The pixel units 2 are arranged in an array. The pixel units 2 each include a sub-pixel 21. The binding region NA includes a first binding region NA1 and a second binding region NA2. The display panel 100 includes pads 3. The pads 3 include a first pad 31 and a second pad 32. The first pad 31 is provided in the first binding region NA1. The second pad 32 is provided in the second binding region NA2. A signal transmitted by the first pad 31 is different from a signal transmitted by the second pad 32.

Referring also to FIG. 2, the display panel 100 may be an OLED display panel. In some embodiments, a basic structure of a light-emitting layer of the OLED display panel often includes an anode, a light-emitting material layer, and a cathode. When an appropriate voltage is supplied by a power supply, holes of the anode are combined with electrons of the cathode in the light-emitting material layer, thereby emitting light. The display panel 100 may also be an inorganic light-emitting diode (ILED) display panel, such as a Micro LED display panel or another light-emitting display panel.

The display panel 100 includes a first display region AA and a binding region NA surrounding the first display region AA, or the display panel 100 includes a first display region AA and a binding region NA partially surrounding the first display region AA. An image is displayed in the first display region AA. The pad 3 is provided in the binding region NA. A light emitting diode (LED) is provided in the binding region NA, so as to display the image and reduce a border width visually. In this case, the binding region where the light-emitting element is provided may be a second display region.

Some pixel units 2 are provided in the first display region AA. In some embodiments, the pixel units 2 may be arranged in an array. The pixel unit 2 may be connected to a data line DL. By controlling the pixel units 2, an image is displayed in the first display region AA. The pixel unit 2 may include multiple sub-pixels 21. The multiple sub-pixels 21 may be a red sub-pixel R, a green sub-pixel G, and a blue sub-pixel B, respectively. In order to distinguish sub-pixels of different colors, sub-pixel 21 in the pixel unit 2 are filled with different patterns, respectively. One column of the sub-pixels 21 of the pixel units 2 may be electrically connected to one data line DL, and one row of the sub-pixels 21 may be electrically connected to at least one selecting signal line SL. When displaying an image, the selecting signal line SL scans one row of the sub-pixels 21 in a time-division manner, and the data line DL transmits a data signal to one column of the sub-pixels 21 in a time-division manner.

The pixel unit is a repetitive unit. The pixel unit may include a red sub-pixel R, a green sub-pixel G, and a blue sub-pixel B, and the pixel unit may also include a red sub-pixel R, a green sub-pixel G, a blue sub-pixel B, and a white sub-pixel W. For an OLED pixel structure, the pixel unit may include one red sub-pixel R, two green sub-pixels G, and one blue sub-pixel B, which is not limited. The embodiment only takes a case where the pixel unit 2 includes the red sub-pixel R, the green sub-pixel G, and the blue sub-pixel B as an example for description.

In some embodiments, the display panel 100 includes pads 3, the pads 3 include a first pad 31 and a second pad 32, the first pad 31 may be configured to transmit a data signal to the sub-pixel 21, and may also be configured to transmit a selecting signal to the sub-pixel 21, and the second pads 32 may be configured to transmit a power signal to the sub-pixel 21, which are not limited.

The first pad 31 is provided in the first binding region NA1. The first binding region NA1 may be a lower binding region. The second pad 32 is provided in the second binding region NA2. The second binding region NA2 may be an upper binding region. The first binding region NA1 and the second binding region NA2 refer to two regions, respectively, rather than an edge. The first pad 31 is provided in the first binding region NA1, and the second pad 32 is provided in the second binding region NA2. The first pad 31 may be opposite to the second pad 32, such that the first pad 31 and the second pad 32 are arranged in different binding regions NA of the first display region AA. By respectively providing the first pad 31 and the second pad 32 in different binding regions NA of the first display region AA, the number of the pads 3 in the lower binding region can be reduced, reducing a manufacturing difficulty of the display panel 100, and increasing the space for the first pad 31 and/or the space for the second pad 32.

In some embodiments, according to different signals transmitted by the first pad 31 and the second pad 32, respectively, the first pad 31 and the second pad 32 can be connected to different signal lines, respectively, which is not limited.

According to the above embodiments, the display panel 100 provided by the embodiments of the present disclosure at least achieves the following effects.

The display panel 100 provided by the embodiments of the present disclosure has the first display region AA and the binding region NA at least partially surrounding the first display region AA and includes pixel units 2 provided in the first display region AA. The pixel units 2 are arranged in an array. The pixel unit 2 includes the sub-pixel 21. The binding region NA includes the first binding region NA1 and the second binding region NA2. The display panel 100 includes the pads 3 including the first pad 31 and the second pad 32. The first pad 31 is provided in the first binding region NA1. The second pad 32 is provided in the second binding region NA2. The signal transmitted by the first pad 31 is different from the signal transmitted by the second pad 32. By providing the first pad 31 and the second pad 32 in different binding regions, respectively, the number of the pads 3 at a single side is reduced, such as reducing the number of the pads 3 in the lower binding region, reducing a manufacturing difficulty of the display panel 100, and increasing the space for the first pad 31 and/or the space for the second pad 32.

In some embodiments, referring also to FIG. 2, along a first direction X, the first binding region NA1 and the second binding region NA2 may be opposite to each other with respect to the first display region AA. In some embodiments, the first binding region NA1 may be a lower binding region. The lower binding region may be a main binding region. The second binding region NA2 may be an upper binding region. The upper binding region may be an auxiliary binding region. The first pads 31 and/or the second pads 32 are arranged along a second direction Y. There may be multiple first pads 31 and multiple second pads 32. The multiple first pads 31 may be arranged along the second direction Y, or the multiple second pads 32 may be arranged along the second direction Y, or the multiple first pads 31 and the multiple second pads 32 may be arranged along the second direction Y. The first pad 31 and the second pad 32 are provided in different binding regions, respectively, and the first pads 31 and/or the second pads 32 are arranged along the second direction Y. The second pad 32 is configured to transmit a power signal to the sub-pixel 21, which increases the display uniformity, avoids that the power signal is led from the first binding region NA1, and increases a spacing between adjacent first pads 31 (for example, a distance from a geometric center of one first pad 31 of the adjacent first pads 31 to a geometric center of the other first pad 31 of the adjacent first pads 31).

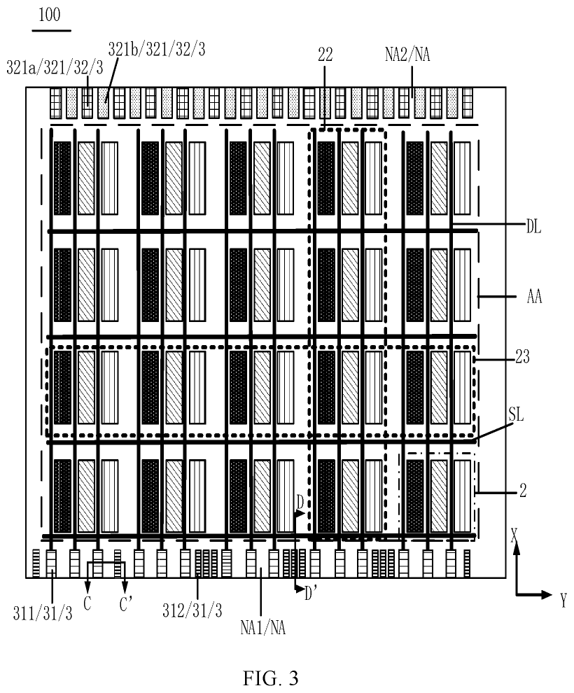

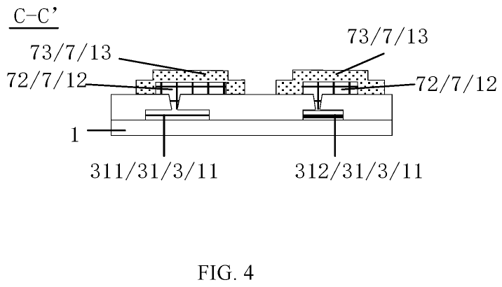

FIG. 3 is a schematic diagram of another display panel according to the present disclosure. FIG. 4 is a schematic diagram along C-C′ shown in FIG. 3. In some embodiments, the display panel includes a data line DL and a selecting signal line SL. At least one of the first pads 31 is at least one data signal pad 311, and the data signal pad 311 is configured to provide a data signal to the data line DL, and/or, at least one of the first pads is at least one selecting signal pad, and the selecting signal pad is configured to provide a selecting signal to the selecting signal line. At least one of the second pads 32 is at least one power signal pad 321, and the power signal pad 321 is configured to provide a power signal to the sub-pixel.

Referring to FIG. 2, the display panel includes a data line DL and a selecting signal line SL. One data line DL may be electrically connected to one column of the sub-pixels 21 in the pixel unit 2. At least one selecting signal line SL may be electrically connected to one row of the sub-pixels 21 in the pixel unit 2.

Referring to FIG. 3, at least one of the first pads 31 may be at least one data signal pad 311. The data signal pad 311 may be located in the lower binding region. The data signal pad 311 is configured to provide a data signal to the data line DL. The data signal pad 311 may correspond to one column of the sub-pixels 21. The data signal pad 311 is electrically connected to the data line DL. In some embodiments, at least three data lines DL are provided for one column of the pixel units 2. Therefore, the number of the data signal pads 311 may correspond to the number of the data lines DL. In some embodiments, when the data signal pads 311 and the selecting signal pads 312 are located in different layers, all of the first pads 31 in a same layer are the data signal pads 311, increasing a spacing between adjacent data signal pads 311 along the second direction, which is not limited.

Referring to FIG. 3, at least one of the first pads 31 may be at least one selecting signal pad 312. The selecting signal pad 312 may be located in the lower binding region. The selecting signal pad 312 is configured to provide a scanning signal to the selecting signal line DL. The selecting signal pad 312 is electrically connected to the selecting signal line SL. According to an actual condition, when the selecting signal pad 312 and the data signal pad 311 are located in different layers, respectively, all of the first pads 31 in a same layer are the selecting signal pads 312, which increases a spacing between adjacent selecting signal pads 312 along the second direction Y, and is not limited.

At least one of the second pads 32 may be at least one power signal pad 321. The power signal pad 321 is configured to provide a power signal to the sub-pixel. With the power signal pad 321 in the second binding region NA2, not only the number of the pads 3 in the first binding region NA1 can be reduced, but also a spacing between adjacent first pads 3 along the second direction Y in the first binding region NA1 can be increased, which reduces a manufacturing difficulty of the pads 3 in the first binding region NA1, and increases a spacing between adjacent power signal pads 321 along the second direction Y.

In some embodiments, referring to FIG. 3 and FIG. 4, at least one of the first pads 31 may be at least one data signal pad 311, and at least one of the first pads 31 may be at least one selecting signal pad 312. The data signal pad 311 is configured to provide a data signal to the data line DL. The selecting signal pad 312 is configured to provide a scanning signal to the selecting signal line SL. The data signal pad 311 and the selecting signal pad 312 may be located in the lower binding region. The data signal pad 311 and the selecting signal pad 312 are located in a same layer, which facilities the manufacture.

In some embodiments, at least one of the power signal pads 321 is at least one first power signal pad 321a, and at least one of the power signal pads 321 is at least one second power signal pad 321b. The first power signal pad 321a is configured to provide a first power signal to the sub-pixel. The second power signal pad 321b is configured to provide a second power signal to the sub-pixel. The first power signal is different from the second power signal.

Referring also to FIG. 2, at least one of the power signal pads 321 is at least one first power signal pad 321a. The first power signal pad 321a is configured to provide a first power signal to the sub-pixel. When the first power signal pad 321a is a PVDD signal pad, the first power signal is a positive power signal. The PVDD signal pad is electrically connected to a PVDD signal line (not shown in the figure). The PVDD signal line may be provided in a latticed manner or on a whole surface. The PVDD signal line is configured to provide the positive power signal. The positive power signal may be a fixed signal. By providing the data signal pad 311 and the first power signal pad 321a in different binding regions, less first power signal pads 321a are provided in the first binding region NA1, which can increase the space for the data signal pad 311, and then designs the data signal pads 311 with a large spacing.

Referring also to FIG. 2, at least one of the power signal pads 321 is at least one second power signal pad 321b. The second power signal pad 321b is configured to provide a second power signal to the sub-pixel 21. When the second power signal pad 321b is a PVEE signal pad, the second power signal may be a negative power signal. The negative power signal may be a fixed signal. The PVEE signal pad may be electrically connected to a PVEE signal line (not shown in the figure). The PVEE signal line may be provided in a latticed manner or on a whole surface. The PVEE signal line is configured to provide the negative power signal. By providing the data signal pad 311 and the second power signal pad 321b in different binding regions, less second power signal pads 321b are provided in the first binding region NA1, which can increase the space for the data signal pad 311 and designs the data signal pads with a large spacing.

In some embodiments, all the power signal pads 321 are first power signal pads 321a. In some embodiments, all the power signal pads 321 are second power signal pads 321b. In the first binding region NA1, the number of the first power signal pads 321a, and/or, the number of the second power signal pads 321b can also be reduced, thereby increasing the space for the data signal pad 311.

Referring also to FIG. 2, the first power signal pad 321a and the second power signal pad 321b are filled with different patterns in FIG. 2, respectively.

In some embodiments, referring also to FIG. 2, along the second direction Y, the first power signal pads 321a and the second power signal pads 321b are arranged alternately. In some embodiments, when at least one of the power signal pads 321 is the at least one first power signal pad 321a, and at least one of the power signal pads 321 is the at least one second power signal pad 321b, the first power signal pads 321a and the second power signal pads 321b are arranged alternately along the second direction Y, such that power signals of different polarities are led to the display panel 100 alternately, which increases display uniformity and prevents a loss of the corresponding power signal.

In some embodiments, referring also to FIG. 2, the display panel includes a pixel column 22. The pixel column 22 includes multiple pixel units 2 arranged along the first direction X. Along the first direction X, the first power signal pad 321a and/or the second power signal pad 321b overlap with the pixel column 22. In some embodiments, each pixel column 22 is provided with the first power signal pad 321a, or, each pixel column 22 is provided with the second power signal pad 321b, or each pixel column 22 is provided with the first power signal pad 321a and the second power signal pad 321b. Multiple second pads 32 are provided to transmit power signals to power signal lines in the display panel, respectively, which increases the display uniformity. In some embodiments, each pixel column 22 may be provided with two or more power signal pads 321, which is not limited.

In some embodiments, referring also to FIG. 3, at least one of the first pads 31 is at least one data signal pad 311, and at least one of the first pads 31 is at least one selecting signal pad 312. Along the second direction Y, the selecting signal pads 312 and the data signal pads 311 are arranged alternately.

In some embodiments, at least one of the first pads 31 is at least one data signal pad 311, and at least one of the first pads 31 is at least one selecting signal pad 312. The selecting signal pad 312 is configured to provide a selecting signal to the selecting signal line. The selecting signal may be a clock signal (such as a clock signal CK or a clock signal XCK) in a scanning driver circuit, a level signal (a high-level signal VGH or a low-level signal VGL), a start signal, etc. The selecting signal pads 312 and the data signal pads 311 are arranged alternately along the second direction Y, and arranged into one row along the second direction Y. For example, one selecting signal pad 312 is provided between three adjacent data signal pads 311, or two or more selecting signal pads 312 are provided between three adjacent data signal pads 311. Specifically, along the second direction Y, there may be three data signal pads 311, one selecting signal pad 312, and three data signal pads 311. Along the second direction, there may also be three data signal pads 311, three selecting signal pads 312, and three data signal pads 311. Along the second direction, the number of the selecting signal pads 312 between three data signal pads 311 and three data signal pads 311 may be adjusted according to an actual condition, which is not limited.

With the above configuration, the selecting signal pads 312 and the data signal pads 311 are arranged alternately along the second direction Y, such that at least one selecting signal pad 312 is arranged between multiple data signal pads 311. In this way, the selecting signal pads 312 can be in one-to-one correspondence with the data signal pads 311, thereby reducing a wiring difficulty, ensuring enough relevant signals, and preventing a loss of the relevant signals.

In some optional embodiments, referring also to FIG. 4, the selecting signal pad 312 and the data signal pad 311 may be provided in a same layer, and the selecting signal line SL and the data line DL may be provided in different layers. The selecting signal pad 312 is electrically connected to the selecting signal line SL only by a jumper.

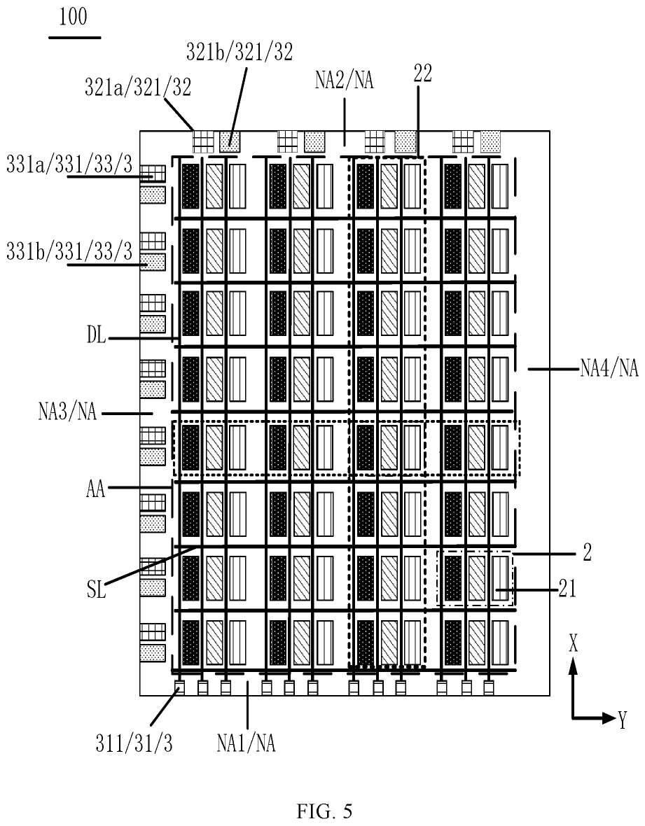

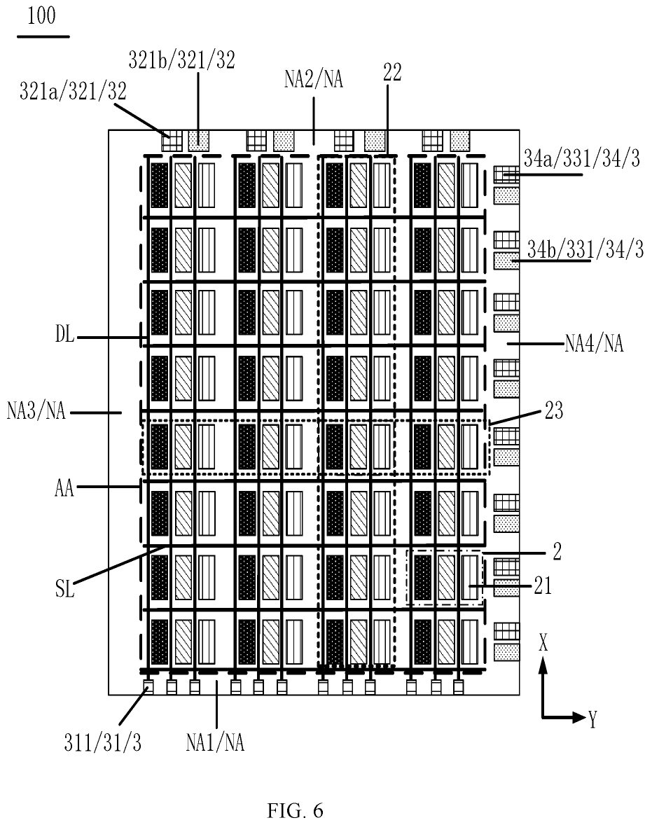

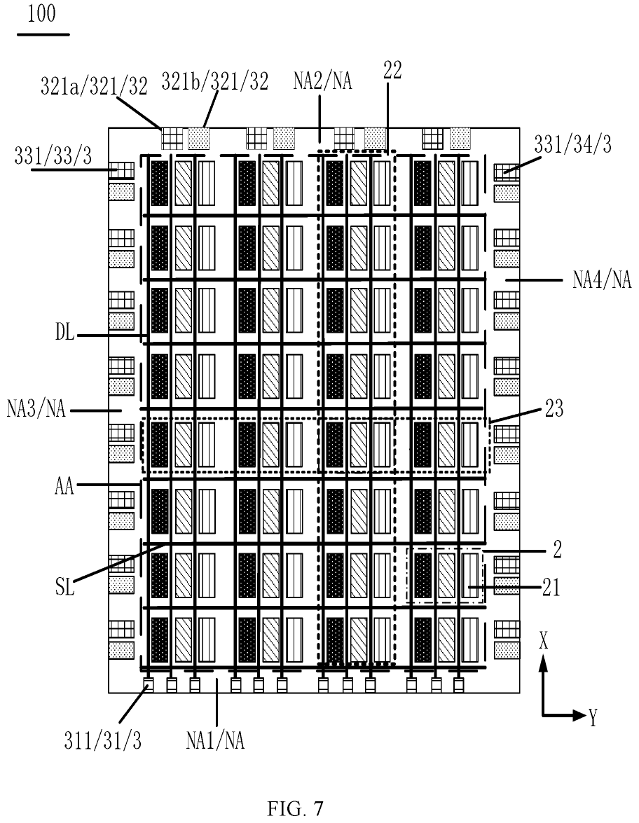

FIG. 5 is a schematic diagram of another display panel according to the present disclosure. FIG. 6 is a schematic diagram of another display panel according to the present disclosure. FIG. 7 is a schematic diagram of another display panel according to the present disclosure. In some embodiments, referring to FIG. 5 to FIG. 7, the display panel 100 has a third binding region NA3 and a fourth binding region NA4 opposite to each other along the second direction Y. The pads 3 includes a third pad 33 provided in the third binding region NA3, and/or, a fourth pad 34 provided in the fourth binding region NA4.

In some embodiments, referring also to FIG. 5, the binding region NA further includes a third binding region NA3 and a fourth binding region NA4. The third binding region NA3 and the fourth binding region NA4 are opposite to each other along the second direction Y. The third binding region NA3 may be a left binding region, and the fourth binding region NA4 may be a right binding region. In some embodiments, the third binding region NA3 may also be a right binding region, and the fourth binding region NA4 may also be a left binding region, which is not limited. The embodiments only takes a case where the third binding region NA3 is the left binding region and the fourth binding region NA4 is the right binding region as an example for description. The pads 3 include the third pad 33 in the third binding region NA3, as shown in FIG. 5. In some embodiments, the pads 3 include the fourth pad 34 in the fourth binding region NA4, as shown in FIG. 6. In some embodiments, the pads 3 include the third pad 33 provided in the third binding region NA3 and the fourth pad 34 provided in the fourth binding region NA4, as shown in FIG. 7. The design may be adjusted flexibly according to actual condition.

Referring to FIG. 7, the lower binding region is a main binding region, while the upper binding region, the left binding region and the right binding region are auxiliary binding regions. Usually, the data signal pad 311 and the selecting signal pad 312 are provided in the lower binding region. In some embodiments, the selecting signal pad may also be provided in other binding regions NA, such as the left binding region or the right binding region, which is not limited.

In some embodiments, at least one of the third pads 33 is at least one power signal pad 331, and/or, at least one of the fourth pads 34 is at least one power signal pad 331.

Referring also to FIG. 5, the third pad 33 is the power signal pad 331 and is provided in the third binding region NA3. The power signal pad 321 in the second pad 32 transmits a power signal to the sub-pixel 21. When the power signal pad 331 in the third pad 33 is also configured to transmit a power signal to the sub-pixel 21, the power signals are transmitted to the sub-pixels 21 from the third binding region NA3 and the second binding region NA2. In this case, the power signal line may be provided through two binding regions, so as to increase the display uniformity.

Referring also to FIG. 6, the fourth pad 34 is the power signal pad 331 and is provided in the fourth binding region NA4. The power signal pad 321 in the second pad 32 transmits a power signal to the sub-pixel 21. When the power signal pad 331 in the fourth pad 34 is also configured to transmit a power signal to the sub-pixel 21, the power signals are transmitted to the sub-pixel 21 from the fourth binding region NA4 and the second binding region NA2. In this case, the power signal line may be led through two binding regions, so as to increase the display uniformity.

Referring to FIG. 7 again, the third pad 33 and the fourth pad 34 are power signal pads 331. The third pad 33 is provided in the third binding region NA3. The fourth pad 34 is provided in the fourth binding region NA4. The power signal pad 321 in the second pad 32 transmits a power signal to the sub-pixel 21. When the power signal pad 331 in the third pad 33 and the power signal pad 331 in the fourth pad 34 are configured to transmit a power signal to the sub-pixel 21, the power signal are transmitted to the sub-pixel 21 from the second binding region NA2, the third binding region NA3, and the fourth binding region NA4. In this case, the power signal line may be provided through three binding regions, which can increase display uniformity.

In some embodiments, the third pads 33 in the third binding region NA3 may be power signal pads 331, or the fourth pads 34 in the fourth binding region NA4 may be power signal pads 331, which can be adjusted according to an actual condition, and is not limited.

The pads 3, such as the first pads 31 and the second pads 32, are provided in the first binding region NA1 and the second binding region NA2. On the above basis, the pads 3, such as the third pads 33 and/or the fourth pads 34, may also be provided in the third binding region NA3 and/or the fourth binding region NA4. Therefore, the pads 3 can be arranged more flexibly.

In some embodiments, the third pad 33 is a first power signal pad 331a, and the fourth pad is a second power signal pad 331b. The first power signal pad 331a is configured to provide a first power signal to the sub-pixel 21. The second power signal pad 331b is configured to provide a second power signal to the sub-pixel 21. The first power signal is different from the second power signal.

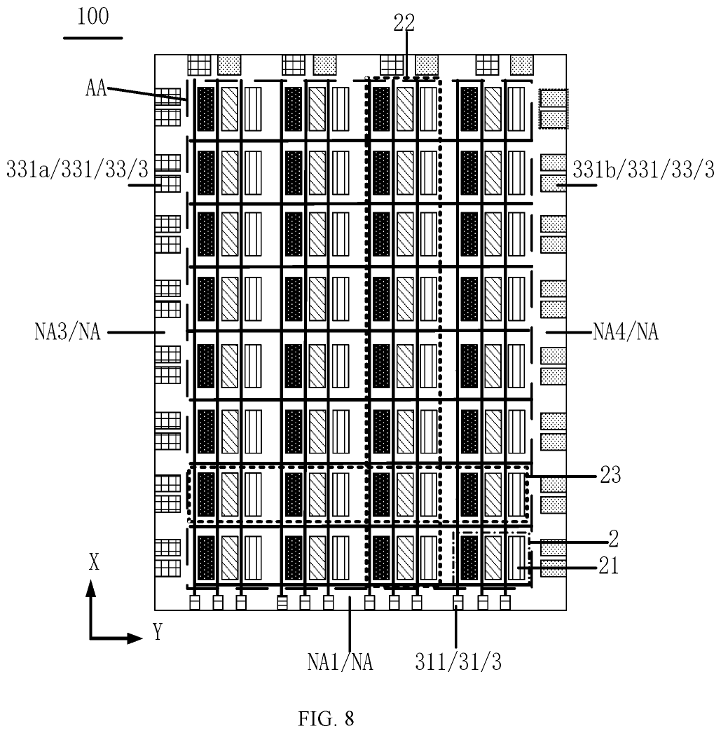

FIG. 8 is a schematic diagram of another display panel according to the present disclosure. In some embodiments, referring to FIG. 8, all of the third pads 33 are first power signal pads 331a. The first power signal pad 331a may be configured to provide a first power signal to the sub-pixel 21. When the first power signal pad 331a is a PVDD signal pad, the first power signal is a positive power signal. The PVDD signal pad is electrically connected to a PVDD signal line (not shown in the figure). The PVDD signal line may be provided in a latticed manner or on a whole surface. The PVDD signal line is configured to provide the positive power signal. The power signal pad 321 in the second pad 32 and the first power signal pad 331a in the third pad 32 are provided in different binding regions, such that signals can be respectively transmitted to the sub-pixel 21 from the first direction X and the second direction Y, thereby increasing display uniformity.

Referring also to FIG. 8, all of the fourth pads are second power signal pads 331b. The second power signal pad 331b may be configured to provide a second power signal the sub-pixel 21. When the second power signal pad 331b is a PVEE signal pad, the second power signal may be a negative power signal. The negative power signal may be a fixed signal. The PVEE signal pad may be electrically connected to a PVEE signal line (not shown in the figure). The PVEE signal line may be provided in a latticed manner or on a whole surface. The PVEE signal line is configured to provide the negative power signal. The power signal pad 321 in the second pad 32 and the second power signal pad 331b in the fourth pad 34 are provided in different binding regions, such that signals can be respectively transmitted to the sub-pixel 21 from the first direction X and the second direction Y, thereby increasing display uniformity.

Multiple first power signal pads 331a are provided. In the third binding region NA3, the first power signal pads 331a are arranged along the first direction X. Multiple second power signal pads 331b are provided. In the fourth binding region NA4, the second power signal pads 331b are arranged along the first direction X. All first power signals are led from the third binding region NA3, and all second power signals are led from the fourth binding region NA4, which can reduce the manufacturing difficulty, save the time and cost, and improve the production efficiency.

FIG. 5 is a schematic diagram of another display panel according to the present disclosure. In some embodiments, referring to FIG. 5, at least one of the third pads 33 is at least one first power signal pad 331a, and at least one of the third pads 33 is at least one second power signal pad 331b. The first power signal pad 331a is configured to provide a first power signal to the sub-pixel 21. The second power signal pad 331b is configured to provide a second power signal to the sub-pixel 21. The first power signal is different from the second power signal. In some embodiments, the first power signal pad 331a may be a PVDD signal pad. The second power signal pad 331b may be a PVEE signal pad. When the first power signal pad 331a is the PVDD signal pad, the first power signal is a positive power signal. When the second power signal pad 331b is the PVEE signal pad, the second power signal may be a negative power signal. While the second binding region NA2 is provided with the power signal pad 321, the third binding region NA3 is also provided with the first power signal pad 331a and the second power signal pad 331b. When the power signal pad 321 in the second binding region NA2 includes the first power signal pad 321a and the second power signal pad 321b, the positive power signal and the negative power signal are respectively transmitted to the sub-pixel 21 along the first direction X and the second direction Y. For example, the positive power signal and the negative power signal are input through two auxiliary binding regions, so as to increase display uniformity.

In some embodiments, referring also to FIG. 5, along the first direction X, the first power signal pads 331a and the second power signal pads 331b are arranged alternately. The first power signal pad 331a and the second power signal pad 331b are provided in the third binding region NA3, and are arranged alternately along the first direction X. When the first power signal pad 331a and the second power signal pad 331b overlap with a pixel row 23 along the second direction Y, power signals of different polarities are input to the display panel 100, thereby increasing the display uniformity. Since the first power signal pad 331a and the second power signal pad 331b are directly manufactured in the third binding region NA3, the process time can be saved, and the efficiency can be improved.

FIG. 6 is a schematic diagram of another display panel according to the present disclosure. In some embodiments, referring to FIG. 6, at least one of the fourth pads 34 is at least one first power signal pad 34a, and at least one of the fourth pads 34 is at least one second power signal pad 34b. In some embodiments, the first power signal pad 34a may be a PVDD signal pad. The second power signal pad 34b may be a PVEE signal pad. When the first power signal pad 34a is the PVDD signal pad, the first power signal is a positive power signal. When the second power signal pad 34b is the PVEE signal pad, the second power signal may be a negative power signal. While the second binding region NA2 is provided with the power signal pad 321, the fourth binding region NA4 is also provided with the first power signal pad 34a and the second power signal pad 34b. When the power signal pad 321 in the second binding region NA2 includes the first power signal pad 321a and the second power signal pad 321b, the positive power signal and the negative power signal are respectively transmitted to the sub-pixel 21 along the first direction X and the second direction Y. For example, the positive power signal and the negative power signal are input through two auxiliary binding regions, so as to increase display uniformity.

In some embodiments, referring to FIG. 6 again, along the first direction X, the first power signal pads 34a and the second power signal pads 34b are arranged alternately. In some embodiments, the first power signal pads 34a and the second power signal pads 34b are formed in the fourth binding region NA4, and are arranged alternately along the first direction X. When the first power signal pad 34a and the second power signal pad 34b overlap with a pixel row 23 along the second direction Y, power signals of different polarities are input to the display panel 100, thereby increasing display uniformity. The second power signal pad 34b is directly manufactured in the fourth binding region NA4, which saves process time, and improve process efficiency.

In some embodiments, referring also to FIG. 5 or FIG. 6, the display panel 100 includes a pixel row 23. The pixel row 23 includes pixel units 2 arranged along the second direction Y. Along the second direction Y, the first power signal pad 331a and/or the second power signal pad 331b overlap with the pixel row 23.

In some embodiments, the pixel units 2 form the pixel row 23 along the second direction Y. The pixel row 23 includes pixel units 2 arranged along the second direction Y. The pixel rows 23 are arranged along the first direction X. The first direction X intersects the second direction Y. In some embodiments, the first direction X is perpendicular to the second direction Y.

Referring also to FIG. 5 or FIG. 6, the first power signal pad 331a is provided corresponding to each pixel row 23, or, the second power signal pad 331b is provided corresponding to each pixel row 23, or the first power signal pad 331a and the second power signal pad 331b are provided corresponding to each pixel row 23. Multiple first power signal pads 331a and multiple second power signal pads 331b transmit power signals to the power signal lines in the display panel, which can increase display uniformity, and particularly improve the transverse uniformity.

In some embodiments, the display panel 100 includes a data line DL. At least one of the first pads 31 is at least one data signal pad 311. The data signal pad 311 is configured to provide a data signal to the data line DL. At least one of the first pads 31 is at least one first power signal pad 31a. The first power signal pad 31a is configured to provide a first power signal to the sub-pixel 21. The second pad 32 is a second power signal pad 32a. The second power signal pad 32a is configured to provide a second power signal to the sub-pixel 21. The first power signal is different from the second power signal.

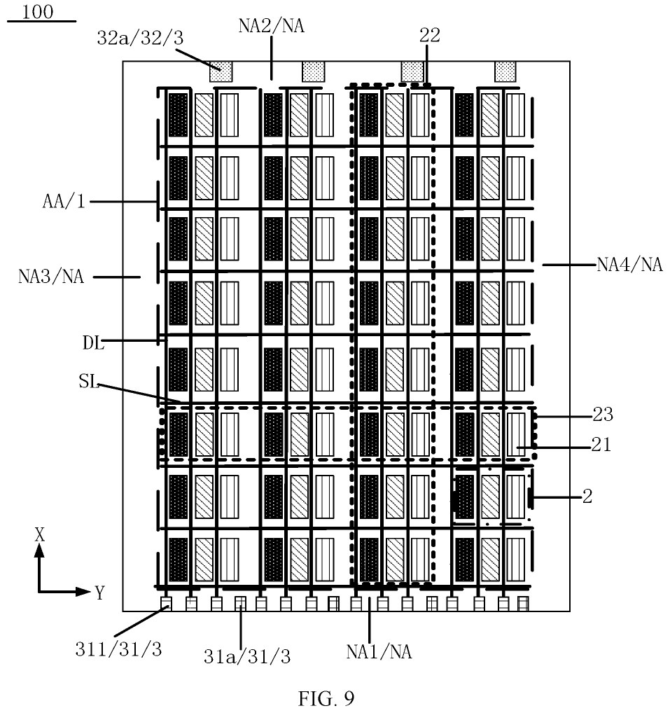

FIG. 9 is a schematic diagram of another display panel according to the present disclosure. In some embodiments, referring to FIG. 9, the display panel 100 includes a data line DL. One data line DL may be electrically connected to one column of the sub-pixels 21 in the pixel unit 2.

At least one of the first pads 31 may be at least one data signal pad 311. The data signal pad 311 may be located in a lower binding region. The data signal pad 311 is electrically connected to the data line DL. The data signal pad 311 is configured to provide a data signal to the data line DL. At least one of the first pads 31 is at least one first power signal pad 31a. The first power signal pad 31a may be a PVDD signal pad. The first power signal pad 31a is configured to provide a first power signal to the sub-pixel 21. The first power signal may be a positive power signal. In some embodiments, the first power signal pad 31a may also be configured to supply a signal line in a shift register, which is not limited. The embodiment only takes a case where the first power signal pad 31a is configured to provide the first power signal to the sub-pixel 21 as an example for description.

The second pad 32 is the second power signal pad 32a. The second power signal pad 32a may be a PVEE signal pad. The second power signal pad 32a is configured to provide a second power signal to the sub-pixel 21. The second power signal may be a negative power signal. The first power signal (positive power signal) may be input from the first binding region NA1, and the second power signal (negative power signal) may be input from the second binding region NA2. The positive power signal and the negative power signal are input jointly through upper and lower sides. In this way, a nonuniform phenomenon of the positive power signal and the negative power signal in the first display region AA can be reduced due to a current and a resistance of power supply metal, thereby increasing display uniformity. Meanwhile, the second power signal pad 32a is provided in the second binding region NA2, which can also reduce the number of the pads 3 in the first binding region NA1, and reduce manufacturing difficulty of the display panel.

Referring to FIG. 9 again, the first power signal pad 31a may be a PVEE signal pad. The first power signal pad 31a is configured to provide a first power signal to the sub-pixel 21. The first power signal may be a negative power signal. The second pad 32 is the second power signal pad 32a. The second power signal pad 32a may be a PVDD signal pad. The second power signal pad 32a is configured to provide a second power signal to the sub-pixel 21. The second power signal may be a positive power signal. The first power signal (positive power signal) may be output from the first binding region NA1, and the second power signal (negative power signal) may be input from the second binding region NA2, which can increase the display uniformity, and reduce the manufacturing difficulty of the display panel.

In some embodiments, referring to FIG. 9 again, along the second direction Y, the first power signal pads 31a and the data signal pads 311 are arranged alternately. In some embodiments, along the second direction Y, the first power signal pad 321a may be located between some data signal pads 311. For example, along the second direction Y, the first power signal pads 31a and the data signal pads 311 are arranged alternately as follows: three data signal pads 311, one first power signal pads 31a, and three data signal pads 311, so that the first power signal pads 31a alternate with every three data signal pads 311. In this way, enough relevant signals are ensured, a loss of the relevant signal is prevented, and winding is reduced.

In some embodiments, referring to FIG. 9 again, when the first direction X is an extension direction of the data line DL, the pixel units 2 form a pixel column 22 along the first direction X. Along the first direction X, the data signal pad 311, the first power signal pad 321a and the second power signal pad 321b overlap with each pixel column 22. The first power signal and the second power signal are input to each pixel column 22, which increases the whole uniformity of the display panel.

In some embodiments, referring to FIG. 2, the display panel 100 includes a data line DL and a selecting signal line SL. The first direction is an extension direction of the data line DL, and the second direction is an extension direction of the selecting signal line SL.

In some embodiments, referring to FIG. 2 again, one data line DL may be electrically connected to one column of the sub-pixels 21 in the pixel unit 2. At least one selecting signal line SL may be electrically connected to one row of the sub-pixels 21. When displaying an image, the selecting signal line SL scans one row of the sub-pixels 21 in a time-division manner, and the data line DL transmits the data signal to one column of the sub-pixels 21 in a time-division manner.

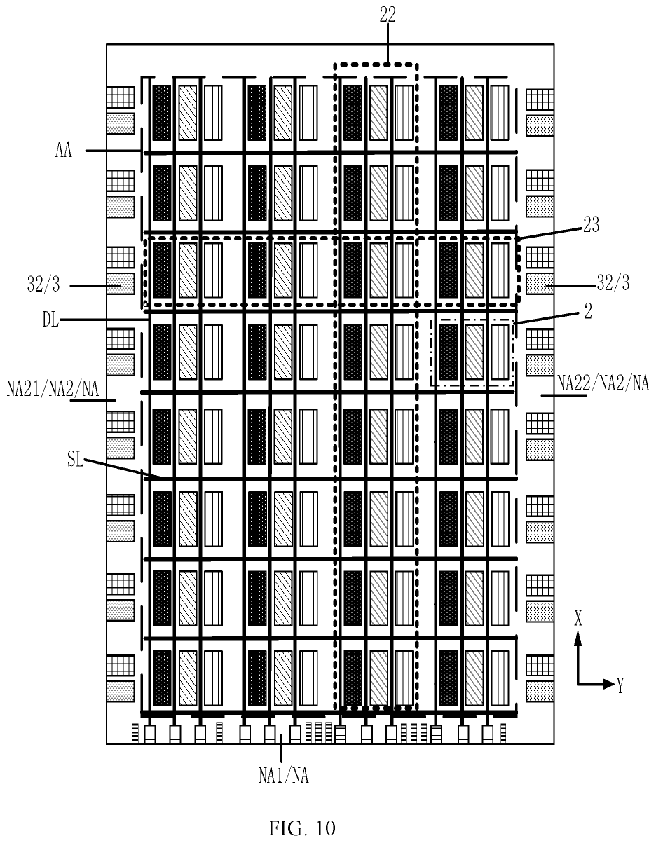

FIG. 10 is a schematic diagram of another display panel according to the present disclosure. In some embodiments, referring to FIG. 10, the first binding region NA1 and the second binding region NA2 are adjacent to each other. The first pads 31 are arranged along a second direction Y. The second pads 32 are arranged along a first direction X. The first direction X intersects the second direction Y.

In some embodiments, referring to FIG. 10 again, the first binding region NA1 may be a lower binding region, and the second binding region NA2 may be a left binding region or a right binding region. The first pads 31 are arranged along a second direction Y. The second pads 32 are arranged along a first direction X. The first direction X intersects the second direction Y. In some embodiments, the first direction X is perpendicular to the second direction Y. When the second pads 32 are power signal pads, by providing the first pads 31 and the second pads 32 in different binding regions, the number of the first pads 31 along the second direction Y can be reduced, and thus a manufacturing difficulty of the first pads 31 is reduced.

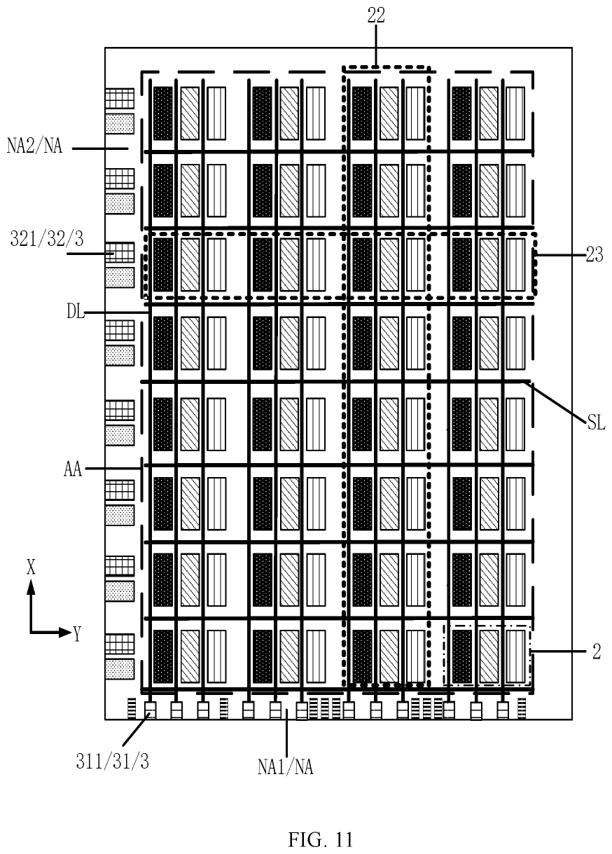

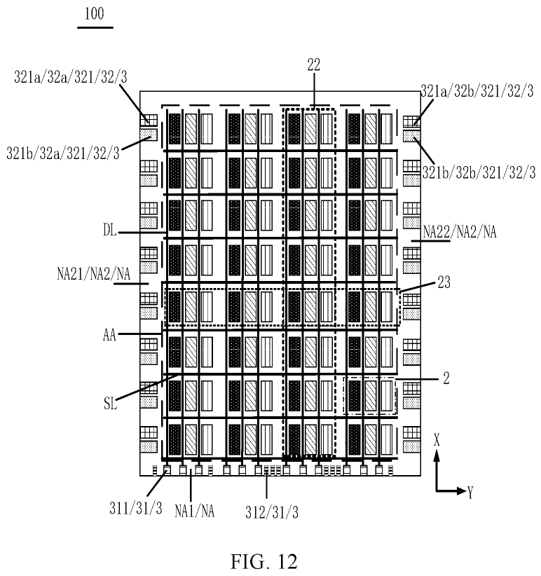

FIG. 11 is a schematic diagram of another display panel according to the present disclosure. FIG. 12 is a schematic diagram of another display panel according to the present disclosure. In some embodiments, referring to FIG. 11 and FIG. 12, the display panel 100 includes a data line DL and a selecting signal line SL. At least one of the first pads 31 is at least one data signal pad 311, and the data signal pad 311 is configured to provide a data signal to the data line DL, and/or, at least one of the first pads 31 is at least one selecting signal pad 312, and the selecting signal pad 312 is configured to provide a selecting signal to the selecting signal line SL. At least one of the second pads 32 is at least one power signal pad 321, and the power signal pad 321 is configured to provide a power signal to the sub-pixel 21.

In some embodiments, referring to FIG. 11, one data line DL may be electrically connected to one column of the sub-pixels 21 in the pixel unit 2. At least one selecting signal line SL may be electrically connected to one row of the sub-pixels 21 in the pixel unit 2.

Referring to FIG. 11 and FIG. 12, the first pad 31 may be a data signal pad 311 configured to provide a data signal to the data line DL, or may be a selecting signal pad 312 configured to provide a selecting signal to the selecting signal line SL. In some embodiments, at least one of the first pads 31 may be at least one data signal pad 311 each configured to provide a data signal to the data line DL, or, may be at least one selecting signal pad 312 each configured to provide a selecting signal to the selecting signal line SL, or, may be at least one data signal pad 311 each configured to provide a data signal to the data line DL. At least another one of the first pads 31 is at least one selecting signal pad 312 each configured to provide a selecting signal to the selecting signal line SL, which can be adjusted according to an actual condition, and is not limited.

The second pad 32 is a power signal pad 321 configured to provide a power signal to the sub-pixel 21, or at least one of the second pads 32 is at least one power signal pad 321 each configured to provide a power signal to the sub-pixel 21. No matter what solution is used, when the power signal pad 321 overlaps with the pixel row 23 along the second direction, the power signal pad 321 in the second binding region NA2 can be used to provide a power signal to the sub-pixel 21, which increases display uniformity, can reduce the number of the pads 3 in the first binding region NA1 to reduce manufacturing difficulty.

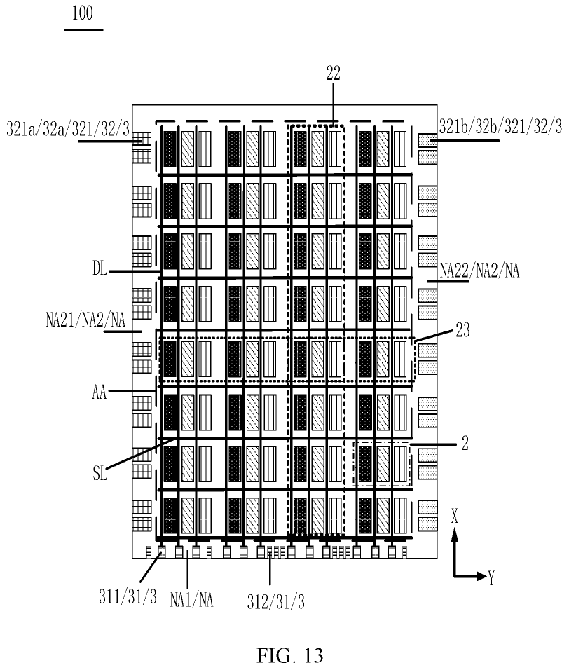

In some embodiments, referring also to FIG. 13, the second binding region NA2 includes a first binding sub-region NA21 and a second binding sub-region NA22. The first binding sub-region NA21 and the second binding sub-region NA22 are opposite to each other along the second direction Y. The first binding sub-region NA21 and the second binding sub-region NA22 are adjacent to the first binding region NA1. At least one of the second pads 32 is at least one first sub-pad 32a. At least one of the second pads is at least one second sub-pad 32b. The first sub-pad 32a is provided in the first binding sub-region NA21. The second sub-pad 32b is provided in the second binding sub-region NA22.

In some embodiments, referring also to FIG. 13, the second binding region NA2 includes a first binding sub-region NA21 and a second binding sub-region NA22. The first binding sub-region NA21 may be a left binding region, the second binding sub-region NA22 may be a right binding region, and the first binding region NA1 may be a lower binding region. In some embodiments, the first binding sub-region NA21 may be a right binding region, the second binding sub-region NA22 may be a left binding region, and the first binding region NA1 may be a lower binding region. There are no limits made thereto. Some embodiments take a case where the first binding sub-region NA21 may be the left binding region, the second binding sub-region NA22 may be the right binding region, and the first binding region NA1 may be the lower binding region as an example for description.

The second pads 32 are first sub-pads 32a; or the second pads are second sub-pads 32b; or at least one of the second pads 32 is at least one first sub-pad 32a, and at least one of the second pads is at least one second sub-pad 32b. No matter what solution is used, the first sub-pad 32a is provided in the first binding sub-region NA21, and the second sub-pad 32b is provided in the second binding sub-region NA22. When the first sub-pad 32a and the second sub-pad 32b are power signal pads, power signals may be transmitted to the sub-pixel 21 along the second direction Y, which increases display uniformity, can reduce the number of the pads 3 along the second direction Y in the first binding region NA1 to increase a spacing between the pads.

FIG. 13 is a schematic diagram of another display panel according to the present disclosure. In some embodiments, referring to FIG. 13, at least one of the power signal pads 321 is at least one first power signal pad 321a, and/or, at least one of the power signal pads 321 is at least one second power signal pad 321b. The first power signal pad 321a is configured to provide a first power signal to the sub-pixel 21. The second power signal pad 321b is configured to provide a second power signal to the sub-pixel 21. The first power signal is different from the second power signal. The first sub-pad 32a is the first power signal pad 321a. The second sub-pad 32b is the second power signal pad 321b.

In some embodiments, referring to FIG. 13, all of the power signal pads 321 in the first binding sub-region NA21 are first power signal pads 321a. In some embodiments referring to FIG. 12, at least one of the power signal pads 321 in the first binding sub-region NA21 is at least one first power signal pad 321a each configured to provide a first power signal for the sub-pixel 21, and the first sub-pad 32a is the first power signal pad 321a. When the first power signal pad 321a is a PVDD signal pad, the first power signal is a positive power signal. The PVDD signal pad is electrically connected to a PVDD signal line (not shown in the figure). The PVDD signal line may be provided in a latticed manner or on a whole surface. The PVDD signal line is configured to provide the positive power signal. When the second pad 32 includes the power signal pad, the power signal pad in the second pad 32 and the first sub-pad 32a are provided in different binding regions, such that signals can be respectively transmitted to the sub-pixel 21 along the second direction Y. When the power signal pad 321 overlaps with the pixel row 23 along the second direction Y, the display uniformity is increased.

Referring to FIG. 13, all of the power signal pads 321 in the second binding sub-region NA22 are second power signal pads 321b. In some embodiments, at least one of the power signal pads 321 in the second binding sub-region NA22 is at least one second power signal pad 321b each configured to provide a second power signal to the sub-pixel 21, and the second sub-pad 32b is the second power signal pad 321b. When the second power signal pad 321b is a PVEE signal pad, the second power signal is a negative power signal. The negative power signal may be a fixed signal. The PVEE signal pad is electrically connected to a PVEE signal line (not shown in the figure). The PVEE signal line may also be provided in a latticed manner or on a whole surface. The PVEE signal line is configured to provide the negative power signal. When the second pad 32 includes the power signal pad, the power signal pad in the second pad 32 and the second sub-pad 32b are provided in different binding regions, such that signals can also be respectively transmitted to the sub-pixel 21 along the second direction Y. When the power signal pad 321 overlaps with the pixel row 23 along the second direction Y, the display uniformity is increased.

Referring to FIG. 13, all of the power signal pads 321 in the first binding sub-region NA21 are first power signal pads 321a. The first power signal pads 321a each are configured to provide a first power signal to the sub-pixel 21. All the power signal pads 321 in the second binding sub-region NA22 are second power signal pads 321b. The second power signal pads 321b each are configured to provide a second power signal toc the sub-pixel 21. When the first power signal pad 321a is a PVDD signal pad, the first power signal is a positive power signal. When the second power signal pad 321b is a PVEE signal pad, the second power signal may be a negative power signal. When the second pad 32 includes the power signal pad (such as a PVDD signal pad and/or a PVEE signal pad), the positive power signal and the negative power signal are respectively transmitted to the sub-pixel 21 along the first direction X and the second direction Y. When the power signal pad 321 overlaps with the pixel row 23 along the second direction Y, and the second pad overlaps with the pixel column 22 along the first direction X, the display uniformity is increased. Since all the power signal pads 321 in the first binding sub-region NA21 are the first power signal pads 321a, and all of the power signal pads 321 in the second binding sub-region NA22 are the second power signal pads 321b, the manufacturing difficulty can also be reduced.

In some embodiments, referring to FIG. 12 and FIG. 13, at least one of the power signal pads 321 is at least one first power signal pad 321a, and/or, at least one of the power signal pads 321 is at least one second power signal pad 321b. The first power signal pad 321a is configured to provide a first power signal to the sub-pixel 21. The second power signal pad 321b is configured to provide a second power signal to the sub-pixel 21. The first power signal is different from the second power signal. At least one of the first sub-pads 32a is the at least one first power signal pad 321a, and at least one of the first sub-pads is the at least one second power signal pad 321b. At least one of the second sub-pads 32b is the at least one first power signal pad 321a, and at least one of the second sub-pads is the at least one second power signal pad 321b.

In some embodiments, referring to FIG. 12 and FIG. 13, the power signal pads 321 are first power signal pads 321a. In some embodiments, at least one of the power signal pads 321 is at least one first power signal pad 321a. The first power signal pad 321a is configured to provide a first power signal for the sub-pixel 21. At least one of the first sub-pads 32a is the at least one first power signal pad 321a. At least one of the second sub-pads 32b is the at least one first power signal pad 321a. When the first power signal pad 321a is a PVDD signal pad, the first power signal is a positive power signal. When the second pad 32 includes the power signal pad, since the power signal pad in the second pad 32, the first sub-pad 32a and the second sub-pad 32b are respectively provided in three binding regions, the power signal may be input to the sub-pixel 21 along the first direction X and the second direction Y. When the power signal pad 321a in each of the first sub-pad 32a and the second sub-pad 32b overlaps with the pixel row 23 along the second direction Y, and the power signal pad in the second pad 32 overlaps with the pixel column 22 along the first direction X, the display uniformity is increased.

The power signal pads 321 are second power signal pads 321b. In some embodiments, at least one of the power signal pads 321 is at least one second power signal pad 321b. The second power signal pad 321b is configured to provide a second power signal to the sub-pixel 21. The first sub-pad 32a is the second power signal pad 321b. The second sub-pad 32b is the second power signal pad 321b. When the second power signal pad 321b is a PVEE signal pad, the second power signal is a negative power signal. When the second pad 32 includes the power signal pad, since the power signal pad in the second pad 32, the first sub-pad 32a and the second sub-pad 32b are respectively provided in three binding regions, the power signal may be input to the sub-pixel 21 along the first direction X and the second direction Y. When the power signal pad 321b in each of the first sub-pad 32a and the second sub-pad 32b overlaps with the pixel row 23 along the second direction Y, and the power signal pad in the second pad 32 overlaps with the pixel column 22 along the first direction X, the display uniformity is increased.

The power signal pads 321 are first power signal pads 321a. The first power signal pads 321a each are configured to provide a first power signal for the sub-pixel 21. At least one of the first sub-pads 32a is at least one first power signal pad 321a. At least one of the second sub-pads 32b is at least one first power signal pad 321a. The power signal pads 321 are second power signal pads 321b. The second power signal pad 321b is configured to provide a second power signal to the sub-pixel 21. The first sub-pad is the second power signal pad 321b. The second sub-pad is the second power signal pad 321b. When the first power signal pad 321a is a PVDD signal pad, the first power signal is a positive power signal. When the second power signal pad 321b is a PVEE signal pad, the second power signal may be a negative power signal. When the second pad 32 includes the power signal pad (such as a PVDD signal pad and/or a PVEE signal pad), the positive power signal and the negative power signal are respectively transmitted to the sub-pixel 21 along the first direction X and the second direction Y. When the power signal pad 321 overlaps with the pixel row 23 along the second direction Y, and the second pad overlaps with the pixel column 22 along the first direction X, the display uniformity is increased.

In some embodiments, referring also to FIG. 12, the first power signal pad 321a and the second power signal pad 321b are arranged alternately along the first direction X. With this solution, power signals of different polarities are alternately input to the display panel 100 to increase display uniformity.

Referring also to FIG. 1, in conventional border-free display manufacturing technology, when side traces are manufactured, a data signal pad 311′, a PVDD signal pad 321′, and PVEE signal pad 322′ are to be provided along a row direction in the lower binding region NA1′. In the high PPI display panel, spaces for pads for the side traces are small-limited. For example, a spacing between the pads is out of the manufacturing capacity, or even out of a golden finger machining capacity of the back flexible circuit board.

When the display panel is applied to a tiled display apparatus, a signal is input from a lower binding region of the tiled display apparatus. Each column of pixel units is supplied with a data signal and a driving voltage signal. Consequently, numerous signal lines and driving voltage lines are provided in the lower binding region of the high PPI tiled display apparatus. For example, for a 57-PPI pixel (a spacing of 444 μm), a spacing between the pads is only 111 μm when no multi-path strobe circuit is provided. For a tiled display apparatus of a higher PPI, the spacing may be out of the golden finger machining capacity of the conventional flexible circuit board.

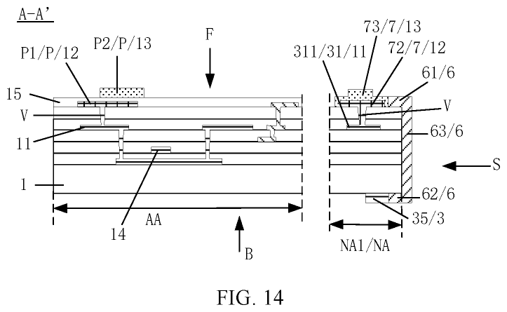

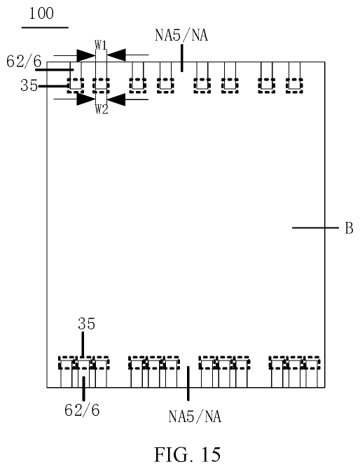

In view of the above technical problem, FIG. 14 is a schematic diagram of A-A′ shown in FIG. 2. FIG. 15 is a schematic diagram of a back surface of a display panel according to the present disclosure. Referring to FIG. 14 and FIG. 15, the display panel 100 in the embodiments includes a front surface F and a back surface B. The binding region NA includes a fifth binding region NA5. The first display region AA, the first binding region NA1, and the second binding region NA2 are located on the front surface F. The fifth binding region NA5 is located on the back surface B. The pads 3 include a fifth pad 35 provided in the fifth binding region NA5. The fifth pad 35 is connected to the first pad 31 and/or the second pad 32 through a connection line 6.

In some embodiments, referring to FIG. 14 and FIG. 15, the display panel includes a front surface F and a back surface B. The front surface F may be a light-outgoing side of the display panel 100. The back surface B may be a backlight side of the display panel 100. The binding region NA includes a fifth binding region NA5. The fifth binding region NA5 is located at the backlight side of the display panel. The pads 3 include a fifth pad 35. The fifth pad 35 is provided in the fifth binding region NA5. The display panel 100 may be an OLED display panel and may also be a Micro LED display panel. The first pad 31 and the second pad 32 are electrically connected to the fifth pad 35 through a connection line 6. The first pad 31 and/or the second pad 32 on the front surface F is electrically connected to the fifth pad 35 on the back surface B through the connection line 6, such that a border width of the display panel 100 can be reduced to provide better viewing experience for a user. When the second pad 32 is configured to transmit a power signal to the sub-pixel 21, not only the display uniform is increased, but also the power signal cannot be output from the first binding region NA1. When the first pad 31 is connected to the fifth pad 35 on the back surface B through the connection line 6, the number of the connection lines 6 can be reduced, a spacing between adjacent connection lines 6 can be increased, and a spacing (a distance from a geometric center of one first pad 31 to a geometric center of the other first pad 31) between adjacent first pads 31 is increased, so as to be within the golden finger machining capacity of the conventional flexible circuit board.

When the display panel 100 is applied to the tiled display apparatus, since the display panel 100 has a reduced border width, a seam between first display regions AA of adjacent display panels 100 cannot be visible by human eyes. Therefore, the whole image displayed by the tiled display apparatus is continuous, and the tiled display apparatus achieves a good display effect. FIG. 14 only takes a case where the first pad 31 is electrically connected to the fifth pad 5 through the connection line 6 as an example for description.

Referring also to FIG. 2, in the high PPI display panel, the first pads 31 and the second pads 32 are respectively provided in the first binding region NA1 and the second binding region NA2. When at least one of the second pads 32 transmits a power signal line to the sub-pixel 21, since the second pads 32 are located in the second binding region NA2, the number of the first pads 31 in the first binding region NA1 is reduced, a space for the connection line 6 can be increased, and the machining capability of the fifth pads 35 on the back surface B can be reduced. For example, by increasing a spacing between the fifth pads 35, and allowing the spacing between the fifth pads 35 to be not smaller than 90 namely reducing a spacing between pads using the connection lines 6, the manufacturing difficulty of the display panel is reduced.

In some embodiments, referring also to FIG. 14, the display panel 100 includes a side surface S connecting the front surface F and the back surface B. The connection line 6 includes a first portion 61, a second portion 62, and a connection portion 63 connecting the first portion 61 and the second portion 62. The first portion 61 is located on the front surface F. The second portion 62 is located on the back surface B. The connection portion 63 is located on the side surface S. In some embodiments, the connection line 6 includes three portions, i.e., the first portion 61, the second portion 62, and the connection portion 63. The connection portion 63 is located between the first portion 61 and the second portion 62. The first portion 61 is located on the front surface F. The second portion 62 is located on the back surface B. The connection portion 63 is located on the side surface S. According to an actual condition, a width of at least one of the first portion 61, the second portion 62, or the connection portion 63 may be adjusted flexibly, which is not limited.

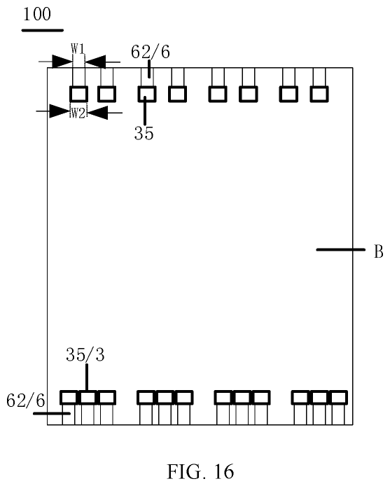

FIG. 16 is a schematic diagram of a back surface of another display panel according to the present disclosure. In some embodiments, referring to FIG. 15 and FIG. 16, along a direction perpendicular to an extension direction of the second portion 62, a width W1 of the second portion 62 is not greater than a width W2 of the fifth pad 35.

In some embodiments, referring to FIG. 15, along a direction perpendicular to an extension direction for the second portion 62, a width W1 of the second portion 62 may be the same as a width W2 of the fifth pad 35. The fifth pad 35 may serve as a portion of the connection line 6, namely the second portion 62. It can be understood that the second portion 62 in the connection line 6 is directly used to replace the fifth pad 35. With the above solution, the fifth pad 35 is not provided, thereby reducing one manufacturing process, and reducing a cost. Meanwhile, by comparing the width of the second portion 62 in the connection line 6 with a width of the normal pad 3, the second portion 62 in the connection line 6 is narrower, thereby further saving a space, and increasing a number of the pads 3.

Referring to FIG. 16, along a direction perpendicular to an extension direction for the second portion 62, a width W1 of the second portion 62 may be smaller than a width W2 of the fifth pad 35. By comparing the width of the fifth pad 35 with the width of the second portion 62, the fifth pad 35 is wider, thereby facilitating signal transmission. When a flexible circuit board or a chip is subsequently bound on the fifth pad 35, a contact area is large to achieve a better binding effect.

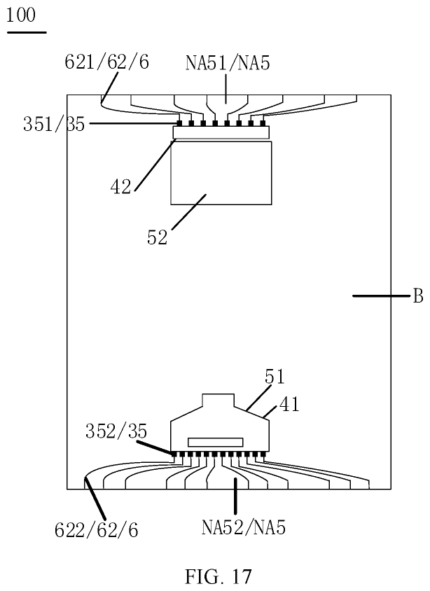

FIG. 17 is a schematic diagram of a back surface of another display panel according to the present disclosure. In some embodiments, referring to FIG. 2 and FIG. 17, the display panel 100 includes a first chip 41 and a second chip 42. The first pad 31 is electrically connected to the first chip 41, and the second pad 32 is electrically connected to the second chip 42. In some embodiments, a signal transmitted by the first chip 41 is different from a signal transmitted by the second ship 42. The signal transmitted by the first pad 31 and the signal transmitted by the second pad 32 are transmitted by different chips. When the first pad 31 is the data signal pad 311, the first chip 41 provides a data signal to the data line DL through the data signal pad 311. When the second pad 32 is the power signal pad 321, the second chip 42 provides a power signal to the power line through the power signal pad 321.

In some embodiments, referring also to FIG. 17, the display panel 100 includes a chip on film (COF) 51 and a first flexible circuit board 52. The COF 51 is electrically connected to the first pad 31. The first chip 41 is provided on the COF 51. The second chip 42 is provided on the display panel 100. The second chip 42 is serially connected between the first flexible circuit board 52 and the second pad 32.

In some embodiments, referring also to FIG. 17, the display panel 100 includes a COF 51 and a first flexible circuit board 52. The display panel 100 is provided with two binding regions NA. The binding regions NA each are configured to bind a driver chip and/or a flexible circuit board. When the binding region NA is configured to bind the flexible circuit board, the display panel 100 may use a COF binding method, namely a grain soft film packaging technology in which the first chip 41 is fixed on the flexible circuit board and no chip is provided additionally. The COF may be a second flexible circuit board. When the binding region NA is configured to bind the driver chip, the display panel may use a chip on glass (COG) binding method. The second chip 42 is directly bound on a substrate of the display panel 100. The first chip 41 is located on the COF 51, and electrically connected to the first pad 31. The second chip 42 is located between the second pad 32 and the first flexible circuit board 52.

Referring to FIG. 2 and FIG. 17, the second portion 62 on the back surface B of the display panel 100 may be of a fan-out shape. The second chip 42 and the COF 51 each are electrically connected to the fifth pad 35 through the second portion 62. In some embodiments, the fifth binding region NA5 includes a third binding sub-region NA51 and a fourth binding sub-region NA52. The third binding sub-region NA51 on the back surface B is opposite to the second binding region NA2 on the front surface F. The fourth binding sub-region NA52 on the back surface B is opposite to the first binding region NA1 on the front surface F. The fifth pad 35 includes third sub-pads 351 and fourth sub-pads 352. The third sub-pads 351 are located in the third binding sub-region NA51. The fourth sub-pads 352 are located in the fourth binding sub-region NA52. The second portion 62 includes first sub-portions 621 and second sub-portions 622. The third sub-pads 351 are electrically connected to the second pads 32 through the first sub-portions 621. The fourth sub-pads 352 are electrically connected to the first pads 31 through the second sub-portions 622.

Referring also to FIG. 17, the third sub-pads 351 are electrically connected to the second chip 42 through the first sub-portions 621. The fourth sub-pads 352 are electrically connected to the COF 51 through the second sub-portions 622. The first pads 31 and the second pads 32 are manufactured in different binding regions, namely a number of the pads in the same binding region NA is reduced. A plurality of the first sub-portions 621 and a plurality of the second sub-portions 622 are scattered along the second direction Y. In this way, a difference between the first sub-portion 621 at the middle and the first sub-portion 621 at the edge and a difference between the second sub-portion 622 at the middle and the second sub-portion 622 at the edge are reduced, thereby increasing signal uniformity.

Some pads (not shown in the figure) are also provided on the COF 51 and/or the second chip 42 and are electrically connected to the fifth pad 35 in the display panel. As shown in FIG. 17, at least one of the fifth pads 35 is exposed. The fifth pad 35 may also be completely covered by the COF 51 and/or the second chip 42, such that a contact area between two pads is increased. In some embodiments, at least one pad (shown in the figure) is provided on the first flexible circuit board 52, and is electrically connected to the pad on the second chip 42.

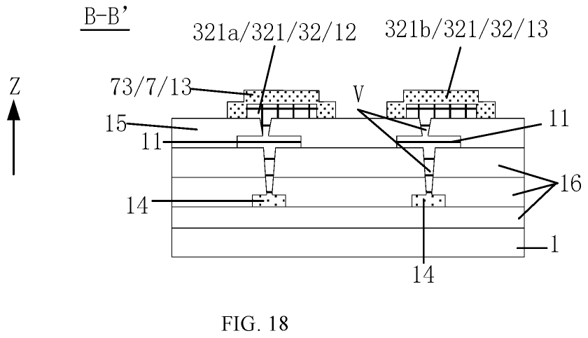

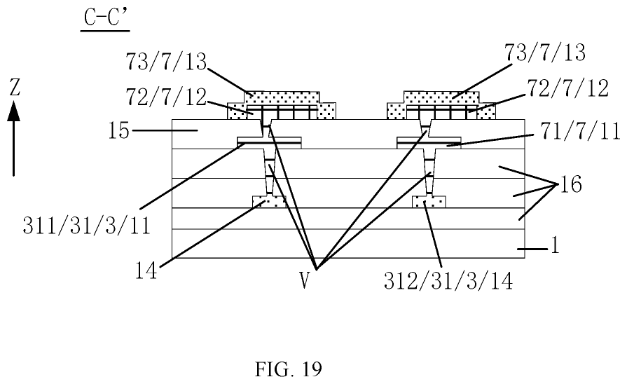

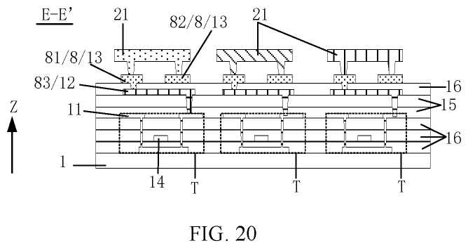

FIG. 18 is a schematic diagram along B-B′ shown in FIG. 2. FIG. 19 is another schematic diagram along C-C′ shown in FIG. 3. FIG. 20 is a schematic diagram along E-E′ shown in FIG. 2. In some embodiments, referring to FIG. 18 to FIG. 20, the first pads 31 and the second pads 32 are located in different layers. By providing the first pads 31 and the second pads 32 in the different layers, a spacing between the first pads 31 and/or a spacing between the second pads 32 can be increased.

In some embodiments, referring to FIG. 2, FIG. 14, FIG. 18, FIG. 19 and FIG. 20, the display panel includes a data line DL and power signal lines P. The display panel includes a substrate 1, a first conductive layer 11, and a second conductive layer 12. Along a thickness direction Z of the display panel 100, the first conductive layer 11 is located between the substrate 1 and the second conductive layer 12. The data line DL is located in the first conductive layer 11. At least one of the power signal lines P is located in the second conductive layer 12. At least one of the first pads 31 is a data signal pad 311. The data signal pad 311 is configured to provide a data signal for the data line DL. The second pads 32 are power signal pads 321. The power signal pad 321 is configured to provide a power signal to the power signal line P. The data signal pad 321 is located in the first conductive layer 11. The power signal pad 321 is located in the second conductive layer 12.

In some embodiments, referring to FIG. 2, FIG. 14, FIG. 19 and FIG. 20, the display panel includes a data line DL and power signal lines P. The display panel includes a substrate 1, a first conductive layer 11, and a second conductive layer 12. The substrate 1 may be made of any flexible or rigid appropriate material. In some embodiments, the substrate may be made of an insulating material. For example, the substrate may be made of a polymer material such as polyimide (PI), polycarbonate (PC), polyether sulfone (PES), polyethylene terephthalate (PET), polyethylene naphthalate (PEN), polyarylate (PAR) or fibre-reinforced plastic (FRP), or a glass material. The first conductive layer 11 and the second conductive layer 12 are made of a material including one or more of molybdenum (Mo), aluminum (Al), neodymium (Nd), silver (Ag) and copper (Cu). Along a thickness direction Z of the display panel 100, the first conductive layer 11 is located between the substrate 1 and the second conductive layer 12. The data line DL is located on the first conductive layer 11. At least one of the power signal lines P is located in the second conductive layer 12. The data line DL and the power signal lines P or at least one of the power signal lines P are provided in different layers, such that signal interference between the data line DL and the power signal line P can be prevented.

Referring to FIG. 18, the first pads 31 or at least one first pad 31 is a data signal pad 311. The data signal pad is configured to provide a data signal to the data line DL. The second pads 32 or at least one second pad 32 is a power signal pad 321. The power signal pad 321 is configured to provide a power signal to the power signal line P. The data signal pad 311 is located in the first conductive layer 11. The power signal pad is located in the second conductive layer 12. By providing the data signal pad 311 and the power signal pad 321 in different layers, a spacing between adjacent first pads 31 can be increased.

In some embodiments, referring to FIG. 14 and FIG. 18, at least one of the power signal lines P is a first signal line P1. At least one of the power signal lines P is a second power signal line P2. At least one of the power signal pads is a first power signal pad 321a. At least one of the power signal pads is a second power signal pad 321b. The first power signal pad 321a is configured to provide a first power signal for the first power signal line P1. The second power signal pad 321b is configured to provide a second power signal for the second power signal line P2. The first power signal is different from the second power signal. The display panel includes a third conductive layer 13. The second conductive layer 12 is located between the third conductive layer 13 and the first conductive layer 11. The first power signal line P1 is located in the second conductive layer 12. The second power signal line P2 is located in the third conductive layer 13. The first power signal pad 321a is located in the second conductive layer 12. The second power signal pad 321b is located in the third conductive layer 13.

In some embodiments, referring to FIG. 14 and FIG. 18, the power signal line P or at least one power signal line P is a first signal line P1. The power signal line P or at least one power signal line P is a second power signal line P2. Referring to FIG. 2 and FIG. 18, the power signal pad 321 or at least one power signal pad 321 is a first power signal pad 321a. The power signal pad 321 or at least one power signal pad 321 is a second power signal pad 321b. The first power signal pad 321a is configured to provide a first power signal to the first power signal line P1. The second power signal pad 321b is configured to provide a second power signal to the second power signal line P2. The first power signal is different from the second power signal. The display panel 100 includes a third conductive layer 13. The third conductive layer 13 includes one or more of molybdenum (Mo), aluminum (Al), neodymium (Nd), silver (Ag) and copper (Cu). The second conductive layer 12 is located between the third conductive layer 13 and the first conductive layer 11.

Referring to FIG. 14 and FIG. 18, the first power signal line P1 is located in the second conductive layer 12. The second power signal line P2 is located in the third conductive layer 13. The first power signal pad 321a is located in the second conductive layer 12. The second power signal pad 321b is located in the third conductive layer 13. It can be understood that the first power signal line P1 and the first power signal pad 321a are located in the same layer, such that winding of the first power signal line P1 can be reduced. The second power signal line P2 and the second power signal pad 321b are located in a same layer, such that winding of the second power signal line P2 can be reduced. The first power signal line P1 and the second power signal line P2 are located in different layers, such that interference between the first power signal and the second power signal can be prevented.

In some embodiments, referring also to FIG. 19, the display panel 100 includes a connection portion 7. The connection portion 7 is at least located in the second conductive layer 12. The display panel 100 includes a first insulating layer 15. Along a thickness direction of the display panel 100, the first insulating layer 15 is located between the first conductive layer 11 and the second conductive layer 12. The connection portion 7 is connected to the data signal pad 311 through a via V. The via V penetrates through the first insulating layer 15.

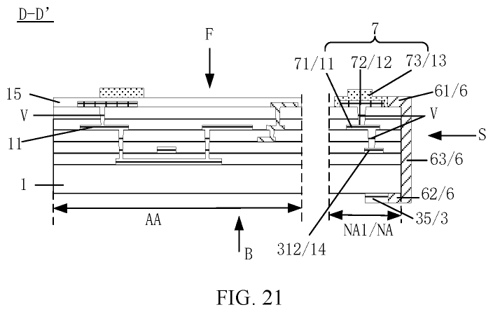

In some embodiments, referring to FIG. 14, when the display panel includes a third conductive layer 13 and a fourth conductive layer 14, the second conductive layer 12 is located between the third conductive layer 13 and the first conductive layer 11, and the fourth conductive layer 14 is located between the first conductive layer 11 and the substrate 1. Since the first conductive layer 11 and the second conductive layer 12 may be connected through the via V, the second conductive layer 12 directly laps with the third conductive layer 13. Referring to FIG. 21, when the display panel includes a connection line 6, the connection line 6 is connected through a connection portion 7. For the selecting signal pad 312, when the selecting signal pad 312 is located in the fourth conductive layer 14, the first conductive layer 11, the second conductive layer 12, and the third conductive layer 13 serve as the connection portion 7. The connection portion 7 includes a first connection sub-portion 71 in the first conductive layer 11, a second connection sub-portion 72 in the second conductive layer 12, and a third connection sub-portion 73 in the third conductive layer 13. Referring to FIG. 4, when the data signal pad 311 and the selecting signal pad 312 are provided in the first conductive layer 11, the second conductive layer 12 and the third conductive layer 13 serve as the connection portion 7. The connection portion 7 includes the second connection sub-portion 72 in the second conductive layer 12, and the third connection sub-portion 73 in the third conductive layer 13. Referring to FIG. 21, when the data signal pad 311 is provided in the first conductive layer 11, the second conductive layer 12 and the third conductive layer 13 serve as the connection portion 7. The connection portion 7 includes the second connection sub-portion 72 in the second conductive layer 12, and the third connection sub-portion 73 in the third conductive layer 13. Referring to FIG. 18, when the first power signal pad 321a is provided in the second conductive layer 12, the third conductive layer 13 serves as the connection sub-portion 73. When the first power signal pad 321a is provided in the second conductive layer 12, the third connection sub-portion 73 in the third conductive layer 13 serves as the connection portion 7.

Referring also to FIG. 20, when the display panel r includes the third conductive layer 13 in the binding region NA, and the second conductive layer 12 is located between the third conductive layer 13 and the first conductive layer 11, the first conductive layer 11, the second conductive layer 12, and the third conductive layer 13 are electrically connected to each other. Referring to FIG. 14, FIG. 18 and FIG. 19, the connection line 6 is led out through the third conductive layer 13. Referring to FIG. 18, the first power signal pad 321a in the second conductive layer 12 may be electrically connected to the first conductive layer 11, the third conductive layer 13 and the fourth conductive layer 14, and the second power signal pad 321b in the third conductive layer 13 may be electrically connected to the first conductive layer 11, the second conductive layer 12 and the fourth conductive layer 14. Referring to FIG. 19, the data signal pad 311 in the first conductive layer 11 may be electrically connected to the second conductive layer 12, the third conductive layer 13 and the fourth conductive layer 14. The selecting signal pad 312 in the fourth conductive layer 14 may also be electrically connected to the first conductive layer 11, the second conductive layer 12, and the third conductive layer 13. In this way, all pads may use a same layer. The overall design is very convenient, and the manufacturing difficulty of the display panel can also be lowered.

In some embodiments, referring to FIG. 4 and FIG. 14, in the binding region NA, no insulating layer is provided between the second conductive layer 12 and the third conductive layer 13. If an organic insulating layer is provided between the second conductive layer 12 and the third conductive layer 13 in the binding region NA, heat is produced at an edge of the organic insulating layer in blade cutting or laser cutting. Therefore, the organic layer at the edge of each of the second pads 32 is removed, and the overall design is simple. The corresponding layer may be provided with a pulling line to omit a jumper from the second pad 32 to the first display region AA.

In some embodiments, referring to FIG. 20, the sub-pixel 21 may be connected to a thin-film transistor T through an electrode 8. The electrode 8 may include a first terminal 81 and a second terminal 82. The first terminal 81 is electrically connected to an anode of the sub-pixel 21. The second terminal 82 is electrically connected to a cathode of the sub-pixel 21. The third conductive layer 13 may form the terminal 8 (the first terminal 81 and the second terminal 82). The first terminal 81 and the second terminal 82 are electrically connected to the thin-film transistor T through a connection electrode 83. The connection electrode 83 is provided in the second conductive layer 12.

When the data signal pad 311 transmits the data signal, and the data line DL is located in the first conductive layer 11, the data signal pad 311 may be connected to a pulling line of the first conductive layer 11 to omit a jumper from the data signal pad 311 to the first display region AA. When the power signal pad 321 transmits the power signal, and the power signal line is located in the second conductive layer 12, the power signal pad 321 may be connected to a pulling line of the second conductive layer 12 to omit a jumper from the second pad 32 to the first display region AA.

A second insulating layer 16 is provided between the first conductive layer 11 and the fourth conductive layer 14 and is also provided between the second conductive layer 12 and the third conductive layer 13 in the first display region AA as well as between the second conductive layer 12 and the fourth conductive layer 14 in the first display region AA. In some embodiments, the second insulating layers 16 may be made of an organic insulating material or an inorganic insulating material, which is not limited. It can be understood that the second insulating layers 16 may be made of different materials.

Referring to FIG. 18 again, the first pad 31 and the second pad 32 each may be laminated for ease of design. Corresponding layers are connected to the first display region AA through pulling lines, which can also reduce a difficulty to design the edge pad 3.

FIG. 21 is a schematic diagram along D-D′ shown in FIG. 3. In some embodiments, referring to FIG. 2 and FIG. 21, the display panel includes a selecting signal line SL. The display panel 100 includes a substrate 1 and a fourth conductive layer 14. Along a thickness direction of the display panel 100, the fourth conductive layer 14 is located at a side of the substrate 1, and the selecting signal line SL is located in the fourth conductive layer 14. At least one first pad 31 is at least one selecting signal pad 312, and the selecting signal pad 312 is configured to provide a selecting signal to the selecting signal line SL. The selecting signal pad 312 is located in the fourth conductive layer 14. In some embodiments, the selecting signal line SL and the selecting signal pad 312 are provided in a same layer, such that a jumper is saved, and winding is reduced. When the data signal pad 311 and the selecting signal pad 312 are provided in the first conductive layer 11, and the selecting signal line SL is provided in the fourth conductive layer 14, since the selecting signal pad 312 and the selecting signal line SL are provided in different layers, a jumper is used to connect the selecting signal pad 312 and the selecting signal line SL.

Referring also to FIG. 21, in the binding region NA, the first conductive layer 11 is connected to the second conductive layer 12 through the via V. When the display panel includes the connection line 6, since the selecting signal pad 312 is provided in the fourth conductive layer 14, the fourth conductive layer 14 is located between the substrate 1 and the first conductive layer 11, and the first conductive layer 11, the second conductive layer 12, and the third conductive layer 13 serve as the connection portion 7. The connection portion 7 includes the first connection sub-portion 71 located in the first conductive layer 11, the second connection sub-portion 72 located in the first conductive layer 12, and the third connection sub-portion 73 located in the third conductive layer 13.

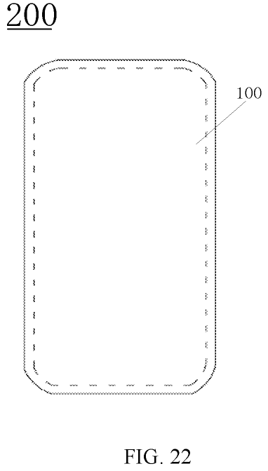

FIG. 22 is a schematic diagram of a display apparatus according to the present disclosure. As shown in FIG. 22, the display apparatus includes any display panel 100 provided by the embodiments. The display apparatus provided by the embodiments of the present disclosure may be any electronic product with a display function, including but not limited to: a television, a notebook computer, a desktop display, a tablet computer, a digital camera, a mobile phone, a smart bracelet, smart glasses, a car monitor, a medical device, an industrial control device, and a touch interactive terminal.

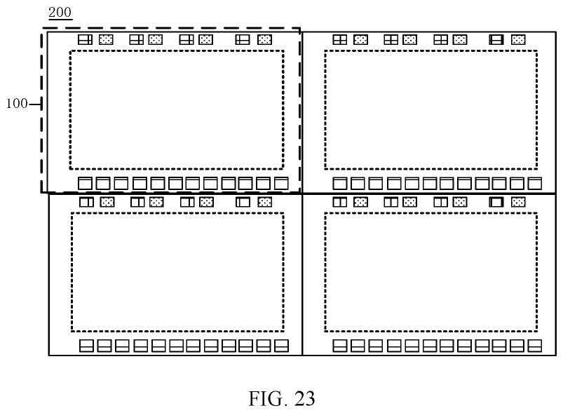

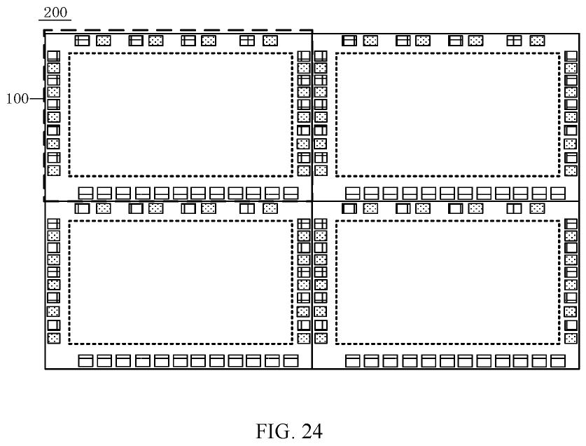

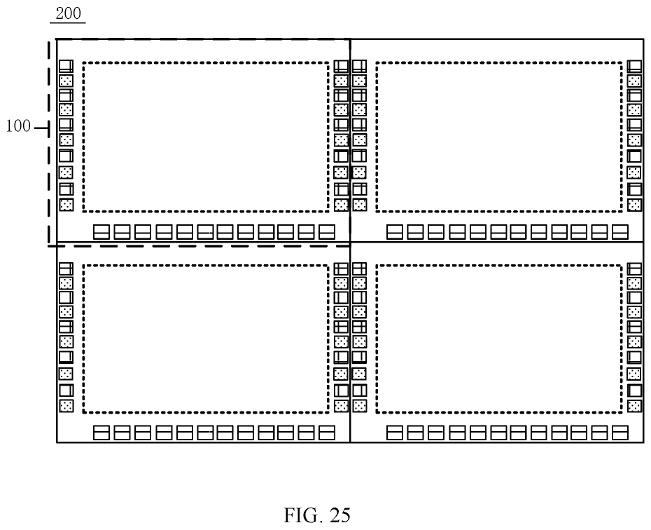

FIG. 23 is a schematic diagram of another display apparatus according to the present disclosure. FIG. 24 is a schematic diagram of another display apparatus according to the present disclosure. FIG. 25 is a schematic diagram of another display apparatus according to the present disclosure. Referring to FIG. 23 to FIG. 25, the display apparatus 200 may be a tiled display apparatus. The tiled display apparatus includes n display panels 100. At least two display panels 100 may be tiled along a first direction X, may also be tiled along a second direction Y, and may be tiled along the first direction X and the second direction Y, n≥2. The structure of the display panel 100 has been described in detail in the foregoing embodiments, and will not be repeated herein. The tiled display apparatus shown in FIG. 23 to FIG. 25 is merely schematic. The tiled display apparatus may be, for example, a Micro LED tiled screen, an OLED tiled screen, a movie screen, and a distant viewing electronic product.

When the display panel is applied to the tiled display apparatus, signals are input from a first binding region, a second binding region, a third binding region, and/or a fourth binding region of the tiled display apparatus. The first binding region is a main binding region. In this case, a data signal pad and a selecting signal pad may be provided in the first binding region. A PVDD signal pad and/or a PVEE signal pad is provided in the second binding region, the third binding region and/or the fourth binding region. In some embodiments, the data signal pad and the selecting signal pad, as well as a power signal pad such as the PVDD signal pad or the PVEE signal pad, may also be provided in the first binding region. Another power signal pad such as the PVEE signal pad or the PVDD signal pad is provided in other binding regions. No matter what solution is used, the number of driving voltage lines in the first binding region can be reduced or the driving voltage line in the first binding region can be directly saved. Therefore, for the high PPI tiled display apparatus, numerous signal lines and driving voltage lines turn out to be unnecessary in the first binding region, and the manufacturing capacity is not beyond the golden finger machining capacity of the conventional flexible circuit board.

According to the above embodiments, the display panel and display apparatus provided by the present disclosure at least achieve the following effects.

According to the display panel and the display apparatus provided by the present disclosure, the display panel includes the first display region and the binding region at least partially surrounding the first display region. The first display region includes pixel units. The pixel units each include the sub-pixel. The binding region includes the first binding region and the second binding region. The display panel includes a pad. The pad includes a first pad and a second pad. The first pad is provided in the first binding region. The second pad is provided in the second binding region. A signal transmitted by the first pad is different from a signal transmitted by the second pad. By providing the first pad and the second pad in different binding regions, the number of the pads at a single side is reduced, manufacturing difficulty of the display panel is reduced, and the space for the first pad and/or the space for the second pad is increased.

Although some specific embodiments of the present disclosure have been explained in detail through examples, those skilled in the art should understand that the above examples are only for illustration and not intended to limit the scope of the present disclosure. Those skilled in the art should understand that modifications can be made to the aforementioned embodiments. The scope of the present disclosure is defined by the appended claims.

What is claimed is:

1. A display panel, having a first display region and a binding region at least partially surrounding the first display region, wherein the display panel comprises:
pixel units arranged in the first display region, at least one of the pixel units comprising at least one sub-pixel; and
pads comprising at least one first pad and at least one second pad, wherein the binding region comprises a first binding region and a second binding region; and
wherein the at least one first pad is provided in the first binding region, the at least one second pad is provided in the second binding region, and a signal transmitted by the at least one first pad is different from a signal transmitted by the at least one second pad.

2. The display panel according to claim 1, wherein the first binding region and the second binding region are located at two opposite sides of the first display region along a first direction; and
wherein at least one of the at least one first pad or one of the at least one second pad is arranged along a second direction, and the second direction intersects the first direction.

3. The display panel according to claim 2, further comprising at least one data line and at least one selecting signal line;
wherein one of the at least one first pad is a data signal pad configured to provide a data signal to one of the at least one data line; and/or, one of the at least one first pad is a selecting signal pad configured to provide a selecting signal to one of the at least one selecting signal line; and
wherein at least one of the at least one second pads is at least one power signal pad configured to provide a power signal to one of the at least one sub-pixel.

4. The display panel according to claim 3, wherein at least one power signal pad comprises a plurality of power signal pads, wherein at least one of the plurality of power signal pads is at least one first power signal pad configured to provide a first power signal for one of the at least one sub-pixel, at least another one of the plurality of power signal pads is at least one second power signal pad configured to provide a second power signal to one of the at least one sub-pixel, and the first power signal is different from the second power signal; and
wherein the at least one first power signal pad comprises at least two first power signal pads, at least one second power signal pad comprises at least two second power signal pads, and the at least two first power signal pads and the at least two second power signal pads are arranged alternately along the second direction.

5. The display panel according to claim 3, wherein at least one power signal pad comprises a plurality of power signal pads, wherein at least one of the plurality of power signal pads is at least one first power signal pad configured to provide a first power signal for one of the at least one sub-pixel, at least another one of the plurality of power signal pads is at least one second power signal pad configured to provide a second power signal to one of the at least one sub-pixel, and the first power signal is different from the second power signal;
wherein the display panel comprises at least one pixel column, wherein at least one of the at least one pixel column comprises at least two of the pixel units arranged along the first direction; and
wherein at least one of one first power signal pad of the at least one first power signal pad or one second power signal pad of the at least one second power signal pad overlap with one pixel column of the at least one pixel column along the first direction.

6. The display panel according to claim 3, wherein the at least one first pad comprises first pads, at least one data line comprises at least two data lines, at least one selecting signal line comprises at least two selecting signal lines, at least two of the first pads are the at least two data lines, at least another two of the first pads are the at least two selecting signal lines; and
wherein the at least two selecting signal pads and the at least two data signal pads are arranged alternately along the second direction.

7. The display panel according to claim 3, wherein the binding region further comprises a third binding region and a fourth binding region opposite to each other along the second direction; and
the pads comprise third pads located in the third binding region, and/or, fourth pads located in the fourth binding region.

8. The display panel according to claim 7, wherein at least one of the third pads is at least one of the at least one power signal pad, or at least one of the fourth pads is at least one of the at least one power signal pad; and
wherein one of the third pads is a first power signal pad configured to provide a first power signal to one of the at least one sub-pixel, one of the fourth pads is a second power signal pad configured to provide a second power signal to one of the at least one sub-pixel, and the first power signal is different from the second power signal; or
wherein at least one of the third pads is at least one first power signal pad configured to provide a first power signal to one of the at least one sub-pixel, at least another one of the third pads is at least one second power signal pad configured to provide a second power signal to one of the at least one sub-pixel, and the first power signal is different from the second power signal; and at least one of the fourth pads is at least one first power signal pad, and at least another one of the fourth pads is at least one second power signal pad.

9. The display panel according to claim 2, further comprising at least one data line;
wherein the at least one first pad comprises first pads, at least one of the first pads is at least one data signal pad configured to provide a data signal to one of the at least one data line, at least another one of the first pads is at least one first power signal pad configured to provide a first power signal to one of the at least one sub-pixel, the at least one second pad is at least one second power signal pad configured to provide a second power signal to one of the at least one sub-pixel, and the first power signal is different from the second power signal; and
wherein the at least one first power signal pad comprises first power signal pads, and at least one data signal pad comprises data signal pads, and the first power signal pads and the data signal pads are arranged alternately along the second direction.

10. The display panel according to claim 1, wherein the first binding region and the second binding region are adjacent to each other; and
wherein the at least one first pad comprises first pads that are arranged along a second direction, the at least one second pad comprises second pads that are arranged along a first direction, and the second direction intersects the first direction.

11. The display panel according to claim 10, further comprising at least one data line and at least one selecting signal line,
wherein at least one of the first pads is at least one data signal pad configured to provide a data signal to one of the at least one data line, or, at least another one of the first pads is at least one selecting signal pad configured to provide a selecting signal to one of the at least one selecting signal line; and
wherein at least one of the second pads is at least one power signal pad configured to provide a power signal to one of the at least one sub-pixel.

12. The display panel according to claim 11, wherein the second binding region comprises a first binding sub-region and a second binding sub-region, the first binding sub-region and the second binding sub-region are opposite to each other along the second direction, and the first binding sub-region and the second binding sub-region each are adjacent to the first binding region; and at least one of the second pads is at least one first sub-pad, at least another one of the second pads is at least one second sub-pad, the at least one first sub-pad is provided in the first binding sub-region, and the at least one second sub-pad is provided in the second binding sub-region; and
wherein at least one of the power signal pads is at least one first power signal pad configured to provide a first power signal to one of the at least one sub-pixel, and/or, at least one of the power signal pads is at least one second power signal pad configured to provide a second power signal to one of the at least one sub-pixel, and the first power signal is different from the second power signal; and the at least one first sub-pad is the at least one first power signal pad, and the at least one second sub-pad is the at least one second power signal pad; or
wherein at least two of the power signal pads are at least two first power signal pads configured to provide a first power signal to one of the at least one sub-pixel, or, at least two of the power signal pads are at least two second power signal pads configured to provide a second power signal to one of the at least one sub-pixel, and the first power signal is different from the second power signal; the at least one first sub-pad comprises first sub-pads, one of the first sub-pads is one of the at least two first power signal pads, and another one of the first sub-pads is one of the at least two second power signal pads; and the at least one second sub-pad comprises second sub-pads, one of the second sub-pads is the another one of the at least two first power signal pads, and another one of the second sub-pads is another one of the at least two second power signal pads.

13. The display panel according to claim 1, wherein the display panel comprises a front surface and a back surface; the binding region further comprises a fifth binding region; the first display region, the first binding region, and the second binding region are located on the front surface; and the fifth binding region is located on the back surface;
wherein the pads comprise fifth pads provided in the fifth binding region, wherein one of the fifth pads is connected to one of the at least one first pad and/or one of the at least one second pad through a connection line;
wherein the display panel comprises a side surface connecting the front surface and the back surface; and the connection line comprises a first portion, a second portion, and a connection portion connecting the first portion and the second portion, wherein the first portion is located on the front surface, the second portion is located on the back surface, and the connection portion is located on the side surface; and
wherein a width of the second portion along a direction perpendicular to an extension direction of the second portion is not greater than a width of one of the fifth pads along the direction perpendicular to the extension direction of the second portion.

14. The display panel according to claim 1, further comprising a first chip, a second chip, a chip on film (COF), and a first flexible circuit board, wherein the at least one first pad is electrically connected to the first chip, and the at least one second pad is electrically connected to the second chip; and
wherein the COF is electrically connected to the at least one first pad, and the first chip is provided on the COF; and the at least one second chip is provided on the display panel and serially connected between the first flexible circuit board and the at least one second pad.

15. The display panel according to claim 1, wherein the at least one first pad and the at least one second pad are located in different layers.

16. The display panel according to claim 15, further comprising:
data lines and power signal lines; and
a substrate, a first conductive layer, and a second conductive layer,
wherein the first conductive layer is located between the substrate and the second conductive layer along a thickness direction of the display panel;
the data lines are located in the first conductive layer, and at least one of the power signal lines is located in the second conductive layer;
at least one of the at least one first pad is at least one data signal pad configured to provide a data signal to one of the data lines, at least one of the at least second pad is at least one power signal pad configured to provide a power signal to one of the power signal lines; and
the at least one data signal pad is located in the first conductive layer, and the at least one power signal pad is located in the second conductive layer.

17. The display panel according to claim 16, wherein at least one of the power signal lines is at least one first power signal line, and at least another one of the power signal lines is at least one second power signal line;
the at least one power signal pad comprises power signal pads, one of the power signal pads is a first power signal pad configured to provide a first power signal to one of the at least one first power signal line, another one of the power signal pads is a second power signal pad configured to provide a second power signal to one of the at least one second power signal line, and the first power signal is different from the second power signal;
the display panel further comprises a third conductive layer, the second conductive layer is located between the third conductive layer and the first conductive layer, the at least one first power signal line is located in the second conductive layer, and the at least one second power signal line is located in the third conductive layer; and
the first power signal pad is located in the second conductive layer, and the second power signal pad is located in the third conductive layer.

18. The display panel according to claim 16, further comprising:
a connection portion located in the second conductive layer; and
a first insulating layer, located between the first conductive layer and the second conductive layer along the thickness direction of the display panel,
wherein the connection portion is connected to one of the at least one data signal pad through a via hole, and the via hole penetrates through the first insulating layer.

19. The display panel according to claim 15, further comprising:
a selecting signal line;
a substrate and a fourth conductive layer that is located at a side of the substrate along a thickness direction of the display panel,
wherein the selecting signal line is located in the fourth conductive layer,
one of the at least first pad is a selecting signal pad configured to provide a selecting signal to the selecting signal line, and
the selecting signal pad is located in the fourth conductive layer.

20. A display apparatus, comprising a display panel, wherein the display panel has a first display region and a binding region at least partially surrounding the first display region, and the display panel comprises:
pixel units arranged in the first display region, at least one of the pixel units comprising at least one sub-pixel; and
pads comprising at least one first pad and at least one second pad,
wherein the binding region comprises a first binding region and a second binding region; and
wherein the at least one first pad is provided in the first binding region, the at least one second pad is provided in the second binding region, and a signal transmitted by the at least one first pad is different from a signal transmitted by the at least one second pad.
